(19) United States
(12) Patent Application Publication
(10) Pub. No.: US 2024/0260381 A1
(43) Pub. Date: Aug. 1, 2024

(54) TRANSPARENT DISPLAY DEVICE WITH TOUCH SENSOR

(71) Applicant: LG Display Co., Ltd., Seoul (KR)

(72) Inventors: MiReum LEE, Paju-si (KR); JaeHee PARK, Paju-si (KR); Dojin KIM, Paju-si (KR)

(73) Assignee: LG Display Co., Ltd., Seoul (KR)

(21) Appl. No.: 18/507,695

(22) Filed: Nov. 13, 2023

(30) Foreign Application Priority Data
Jan. 27, 2023 (KR) 10-2023-0011139

(51) Int. Cl. H10K 59/40; G06F 3/041; G06F 3/044; H10K 59/124; H10K 59/126; H10K 59/131

(52) U.S. Cl. CPC H10K 59/40; G06F 3/0412; G06F 3/0418; G06F 3/0443; G06F 3/0446; H10K 59/124; H10K 59/126; H10K 59/131; G06F 2203/04107; G06F 2203/04111

(57) ABSTRACT

A transparent display device with a touch sensor can include a plurality of subpixels disposed in a non-transmissive area of a substrate, the plurality of subpixels including a light emitting element having an anode electrode, a light emitting layer and a cathode electrode; a touch sensor disposed in a transmissive area of the substrate, the touch sensor including a touch sensor electrode. Also, the transparent display device can include a touch line disposed between the substrate and the anode electrode in the non-transmissive area, the touch line being configured to supply a touch sensing voltage to the touch sensor; and a shielding layer disposed between the touch line and the anode electrode in the non-transmissive area.

### CROSS-REFERENCE TO RELATED APPLICATIONS

This application claims priority under 35 U.S.C. § 119(a) to Korean Patent Application No. 10-2023-0011139 filed in the Republic of Korea on Jan. 27, 2023, the entirety of which is hereby incorporated by reference as if fully set forth herein.

### BACKGROUND

### Technical Field

The present disclosure relates to a transparent display device with a touch sensor.

### Description of the Related Art

Recently, studies for a transparent display device in which a user can view objects or images positioned at an opposite side through the display device are actively ongoing. The transparent display device includes a display area on which an image is displayed, in which the display area can include a transmissive area capable of transmitting external light and a non-transmissive area, and can have high light transmittance through the transmissive area for seeing through the transparent display device and viewing objects located on the other side.

A transparent display device can be provided with a plurality of touch sensors and a plurality of touch lines to implement a touch function.

The transparent display device in the related art has technical problems in that it is not easy to form the plurality of touch sensors and the plurality of touch lines, and the manufacturing process is complicated. Also, light transmittance can be reduced and impaired due to the plurality of touch sensors and the plurality of touch lines. In addition, in the transparent display device, electrodes for image display, a plurality of driving lines, a plurality of touch sensors for touch, and a plurality of touch lines can be disposed in a narrow area can affect each other with noise, interference and parasitic capacitance, which can impair image quality and reduce touch sensing accuracy.

### SUMMARY OF THE DISCLOSURE

The present disclosure has been made in view of the various technical problems in the related art including the above problems.

It is an object of the present disclosure to provide a transparent display device that can minimize loss of light transmittance due to a touch sensor and a touch line.

It is another object of the present disclosure to provide a transparent display device that can ensure high touch performance.

In addition to the objects of the present disclosure as mentioned above, additional objects and features of the present disclosure will be clearly understood by those skilled in the art from the following description of the present disclosure.

In accordance with an aspect of the present disclosure, the above and other objects can be accomplished by the provision of a transparent display device with a touch sensor, the transparent display device can include a substrate provided with a transmissive area and a non-transmissive area, a plurality of subpixels provided in the non-transmissive area, including a light emitting element consisting of an anode electrode, a light emitting layer and a cathode electrode, a touch sensor disposed in the transmissive area, including a touch sensor electrode, a touch line provided between the substrate and the anode electrode in the non-transmissive area, supplying a touch sensing voltage to the touch sensor, and a shielding layer provided between the touch line and the anode electrode in the non-transmissive area.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic plan view illustrating a transparent display panel according to an embodiment of the present disclosure;

FIG. 2 is a schematic view illustrating an example of pixels provided in an area A of FIG. 1 according to an embodiment of the present disclosure;

FIG. 3 is a view illustrating an example of signal lines, touch lines, a touch sensor and a shielding layer, which are provided in an area B of FIG. 2 according to an embodiment of the present disclosure;

FIG. 4 is a view illustrating a connection relation between a plurality of touch blocks and a plurality of touch lines according to an embodiment of the present disclosure;

FIG. 5 is a view illustrating a connection relation between a plurality of touch lines and a plurality of touch sensors in one touch block according to an embodiment of the present disclosure;

FIG. 6 is a cross-sectional view illustrating an example of line I-I′ of FIG. 3 according to an embodiment of the present disclosure;

FIG. 7 is a cross-sectional view illustrating an example of line II-II′ of FIG. 3 according to an embodiment of the present disclosure;

FIG. 8A is a circuit view illustrating parasitic capacitance generated between a touch line and signal lines according to an embodiment of the present disclosure;

FIG. 8B is a view illustrating an influence of a touch signal on a light emitting element according to an embodiment of the present disclosure;

FIG. 9A is a circuit view illustrating parasitic capacitance when a shielding layer is provided between a touch line and an anode electrode of a light emitting element according to an embodiment of the present disclosure;

FIG. 9B is a circuit view illustrating an influence of a touch signal on a light emitting element when a shielding layer is provided between a touch line and an anode electrode of a light emitting element according to an embodiment of the present disclosure;

FIG. 10 is a view illustrating a ghost touch defect phenomenon;

FIG. 11 is a view illustrating an influence of a planarization layer and a bank, which are provided in a transparent display panel, on a ghost touch defect according to an embodiment of the present disclosure;

FIG. 12 is a view illustrating another example of signal lines, touch lines, a touch sensor and a shielding layer, which are provided in an area B of FIG. 2 according to an embodiment of the present disclosure;

FIG. 13 is a cross-sectional view illustrating an example of line III-III′ of FIG. 12 according to an embodiment of the present disclosure; and

FIG. 14 is a cross-sectional view illustrating an example of a first branch line cut by laser according to an embodiment of the present disclosure.

### DETAILED DESCRIPTION OF THE EMBODIMENTS

Advantages and features of the present disclosure, and implementation methods thereof will be clarified through the following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, dimensions (e.g., length, width, height, thickness, radius, diameter, area, etc.), a ratio, an angle, and a number of elements disclosed in the drawings for describing embodiments of the present disclosure are merely an example, and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure important points of the present disclosure, the detailed description will be omitted. In a situation where “comprise,” “have,” and “include” described in the present specification are used, another part can be added unless “only” is used. The terms of a singular form can include plural forms unless referred to the contrary.

In construing an element, the element is construed as including an error range although there is no explicit description.

In describing a position relationship, for example, when the position relationship is described as “upon,” “above,” “below-,” and “next to,” one or more portions can be arranged between two other portions unless “just” or “direct” is used.

It will be understood that, although the terms “first,” “second,” etc., can be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first,” “second,” etc., can be used. These terms are intended to identify the corresponding elements from the other elements, and basis, order, or number of the corresponding elements are not limited by these terms. The expression that an element is “connected” or “coupled” to another element should be understood that the element can directly be connected or coupled to another element but can directly be connected or coupled to another element unless specially mentioned, or a third element can be interposed between the corresponding elements.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in co-dependent relationship.

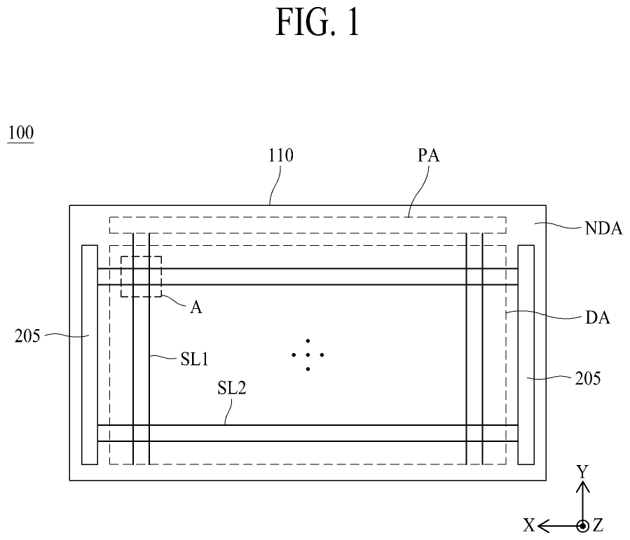

FIG. 1 is a schematic plan view illustrating a transparent display panel according to an embodiment of the present disclosure.

Hereinafter, X axis indicates a line parallel with a scan line, Y axis indicates a line parallel with a data line, and Z axis indicates a height direction of a transparent display device 100.

Although a description has been described based on that the transparent display device 100 according to one embodiment of the present disclosure is embodied as an organic light emitting display device, the transparent display device 100 can be embodied as a liquid crystal display device, a plasma display panel (PDP), a Quantum dot Light Emitting Display (QLED) or an Electrophoresis display device.

Referring to FIG. 1, a transparent display device according to one embodiment of the present disclosure includes a transparent display panel 110. The transparent display panel 110 can include a display area DA provided with pixels to display an image, and a non-display area NDA that does not display an image.

The display area DA can be provided with first signal lines SL1, second signal lines SL2 and the pixels. The non-display area NDA can be provided with a pad area PA in which pads are disposed, and at least one gate driver 205.

The first signal lines SL1 can be extended in a first direction (e.g., Y-axis direction). The first signal lines SL1 can cross the second signal lines SL2 in the display area DA. The second signal lines SL2 can be extended in the display area DA in a second direction (e.g., X-axis direction). The pixel can be provided in an area where the first signal line SL1 are provided or an area where the first signal line SL1 and the second signal line SL2 cross each other and emits predetermined light to display an image.

The gate driver 205 is connected to the scan lines and supplies scan signals to the scan lines. The gate driver 205 can be disposed in the non-display area NDA on one side or both sides of the display area DA of the transparent display panel 110 by a gate driver in panel (GIP) method or a tape automated bonding (TAB) method.

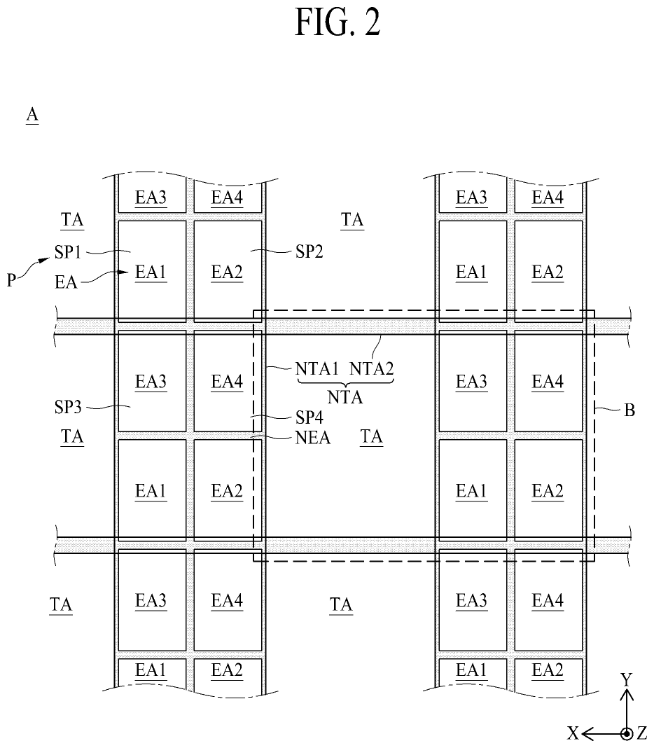

The transparent display panel 110 can further include a touch line and a touch sensor in addition to the first signal line SL1, the second signal line SL2 and the pixel, in order to implement a touch function. A detailed description of the touch line and the touch sensor will be described later with reference to FIGS. 2 to 9.

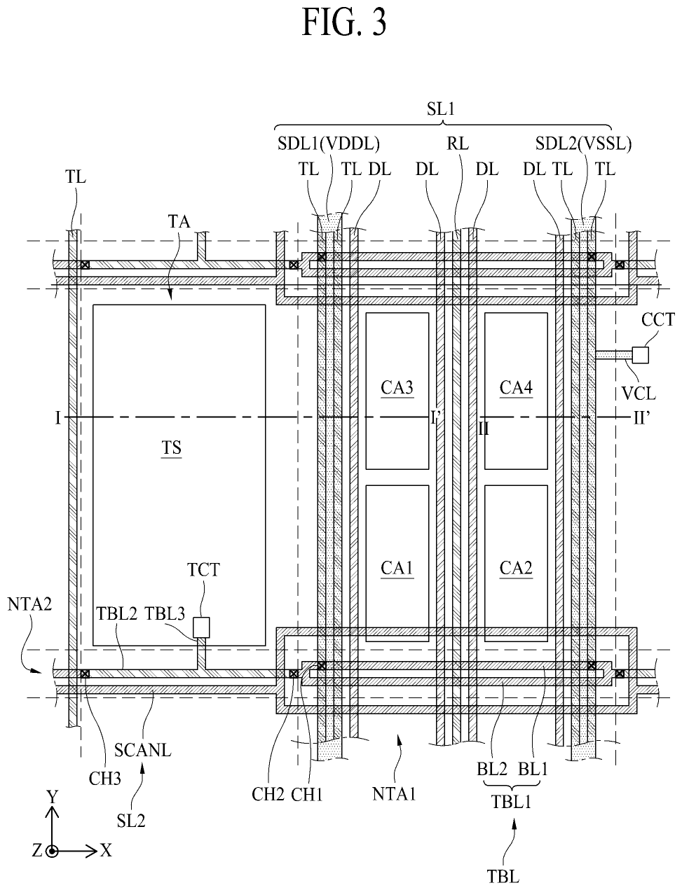

FIG. 2 is a schematic view illustrating an example of a pixel provided in an area A of FIG. 1 according to an embodiment, and FIG. 3 is a view illustrating an example of signal lines, touch lines and a touch sensor, which are provided in an area B of FIG. 2 according to an embodiment.

The display area DA, as shown in FIG. 2, includes a transmissive area TA and a non-transmissive area NTA. The transmissive area TA is an area through which most of externally incident light passes through, and the non-transmissive area NTA is an area through which most of externally incident light fails to pass through or is blocked. For example, the transmissive area TA can be an area where light transmittance is greater than a %, and the non-transmissive area NTA can be an area where light transmittance is smaller than R %. At this time, a is greater than 3. A user can view an object or background arranged or located behind a rear surface of the transparent display panel 110 due to the transmissive area TA.

The non-transmissive area NTA can include a first non-transmissive area NTA1, a second non-transmissive area NTA2 and a plurality of pixels P. Pixels P can be provided to at least partially overlap with at least one of the first signal line SL1 and the second signal line SL2, thereby emitting predetermined light to display an image. A light emission area EA can correspond to an area, from which light is emitted, in the pixel P.

Each of the pixels P, as shown in FIG. 2, can include at least one of a first subpixel SP1, a second subpixel SP2, a third subpixel SP3 and a fourth subpixel SP4. The first subpixel SP1 can include a first light emission area EA1 emitting light of a first color. The second subpixel SP2 can include a second light emission area EA2 emitting light of a second color. The third subpixel SP3 can include a third light emission area EA3 emitting light of a third color. The fourth subpixel SP4 can include a fourth light emission area EA4 emitting light of a fourth color.

The first to fourth light emission areas EA1, EA2, EA3 and EA4 can emit light of different colors. For example, the first light emission area EA1 can emit light of a green color. The second light emission area EA2 can emit light of a red color. The third light emission area EA3 can emit light of a blue color. The fourth light emission area EA4 can emit light of a white color. However, the light emission areas are not limited to this example. Also, the arrangement order of the subpixels SP1, SP2, SP3 and SP4 can be changed in various ways.

The first non-transmissive area NTA1 can be extended in a first direction (e.g., Y-axis direction) in a display area DA, and can be disposed to at least partially overlap with light emission areas EA1, EA2, EA3 and EA4. A plurality of first non-transmissive areas NTA1 can be provided in the transparent display panel 110, and the transmissive area TA can be provided between two adjacent first non-transmissive areas NTA1. In the first non-transmissive area NTA1, first signals lines SL1 extended in the first direction (e.g., Y-axis direction) can be disposed to be spaced apart from each other.

For example, the first signal lines SL1 can include at least one of a pixel power line VDDL, a common power line VSSL, a reference line RL and data lines DL.

The pixel power line VDDL can supply a first power source to a driving transistor DTR of each of subpixels SP1, SP2, SP3 and SP4 provided in the display area DA.

The common power line VSSL can supply a second power source to a cathode electrode of the subpixels SP1, SP2, SP3 and SP4 provided in the display area DA. At this time, the second power source can be a common power source commonly supplied to the subpixels SP1, SP2, SP3 and SP4.

The common power line VSSL can supply the second power source to the cathode electrode through a cathode contact electrode CCT. The cathode contact electrode CCT can be provided between the transmissive area TA and the common power line VSSL. A power connection line VCL can be disposed between the common power line VSSL and the cathode contact electrode CCT. One end of the power connection line VCL can be connected to the common power line VSSL and the other end thereof can be connected to the cathode contact electrode CCT. The cathode electrode can be connected to the cathode contact electrode CCT. As a result, the cathode electrode can be electrically connected to the common power line VSSL through the power connection line VCL and the cathode contact electrode CCT.

The reference line RL can supply an initialization voltage (or sensing voltage) to the driving transistor DTR of each of the subpixels SP1, SP2, SP3 and SP4 provided in the display area DA. The reference line RL can be disposed between the plurality of data lines DL. For example, the reference line RL can be disposed at the center of the four data lines DL, that is, between the second data line DL and the third data line DL. Also, the four data lines DL can be symmetrically arranged with respect to the reference line RL, but embodiments are not limited thereto.

The reference line RL can be diverged and connected to the plurality of subpixels SP1, SP2, SP3 and SP4. In detail, the reference line RL can be connected to circuit elements of the plurality of subpixels SP1, SP2, SP3 and SP4 to supply an initialization voltage (or sensing voltage) to each of the subpixels SP1, SP2, SP3 and SP4.

Each of the data lines DL can supply a data voltage to the subpixels SP1, SP2, SP3 and SP4. For example, one data line DL can supply a first data voltage to a first driving transistor of the first subpixel SP1, the other data line DL can supply a second data voltage to a second driving transistor of the second subpixel SP2. Another data line DL can supply a third data voltage to a third driving transistor of the third subpixel SP3 and another data line DL can supply a fourth data voltage to a fourth driving transistor of the fourth subpixel SP4.

The first signal lines SL1 can further include touch lines TL. In the transparent display panel 110 according to one embodiment of the present disclosure, the touch line TL can be further disposed in the first non-transmissive area NTA1. At least two touch lines TL can be provided in the first non-transmissive area NTA1. When the plurality of touch lines TL are disposed in the transmissive area TA of the transparent display panel 110, light transmittance may be deteriorated due to the plurality of touch lines TL and the transparent ability or see-through capability of the transparent display panel 110 may be impaired due to the touch lines TL.

Also, a slit, specifically an elongated linear or rectangular shape, can be provided between the plurality of touch lines TL. When external light passes through the slit, a diffraction phenomenon can occur. According to the diffraction phenomenon, light corresponding to plane waves can be changed to spherical waves as the light passes through the slit, and an interference phenomenon can occur in the spherical waves. Therefore, constructive interference and destructive interference occur in the spherical waves, whereby the external light that has passed through the slit can have irregular light intensity. As a result, in the transparent display panel 110, definition of an object or image positioned at an opposite side can be reduced or appear fuzzy or less sharp. For this reason, there are some technical benefits to dispose the plurality of touch lines TL in the first non-transmissive area NTA1 rather than in the transmissive area TA.

A plurality of touch lines TL can be disposed between first signal lines SL1 in the first non-transmissive area NTA1 and a transmissive area TA as shown in FIG. 3. For example, four touch lines TL can be disposed in one first non-transmissive area NTA1. Two touch lines TL can be disposed between the circuit areas CA1, CA2, CA3 and CA4 and the transmissive area TA disposed on the right of the circuit areas CA1, CA2, CA3 and CA4. The other two touch lines TL can be disposed between the circuit areas CA1, CA2, CA3 and CA4 and the transmissive area TA disposed on the left of the circuit areas CA1, CA2, CA3 and CA4, but are not limited to this arrangement. The plurality of touch lines TL are required so as not to overlap circuit areas CA1, CA2, CA3 and CA4 in which circuit elements are disposed, and various modifications can be made in the arrangement order of the plurality of touch lines TL with the first signal lines SL1. Also, the touch lines TL can be symmetrically arranged with respect to the reference line RL, but embodiments are not limited thereto.

The transparent display panel 110 according to one embodiment of the present disclosure is provided with a pixel P between adjacent transmissive areas TA. The pixel P can include light emission areas EA1, EA2, EA3 and EA4 in which a light emitting element is disposed to emit light (e.g., EA1, EA2, EA3 and EA4 can correspond to four different colored subpixels within the pixel P). Since the non-transmissive area NTA in the transparent display panel 110 has a small area, one or more circuit elements can be disposed to at least partially overlap with the light emission areas EA1, EA2, EA3 and EA4.

In the transparent display panel 110 according to one embodiment of the present disclosure, the plurality of touch lines TL do not overlap with the circuit areas CA1, CA2, CA3 and CA4, whereby parasitic capacitance of the touch lines TL due to the circuit elements can be reduced or minimized. Furthermore, the transparent display panel 110 according to one embodiment of the present disclosure can reduce a horizontal distance difference between the touch lines TL and improve uniformity of the parasitic capacitance.

The second non-transmissive area NTA2 can be extended in the display area DA in a second direction (e.g., X-axis direction), and can be disposed to at least partially overlap with the light emission areas EA1, EA2, EA3 and EA4. A plurality of second non-transmissive areas NTA2 can be provided in the transparent display panel 110, and the transmissive area TA can be provided between two adjacent second non-transmissive areas NTA2. The second signal line SL2 can be disposed in the second non-transmissive area NTA2.

The second signal line SL2 is extended in a second direction (e.g., X-axis direction), and can include, for example, a scan line SCANL. The scan line SCANL can supply a scan signal to subpixels SP1, SP2, SP3 and SP4 of the pixel P.

The second signal line SL2 can further include a touch bridge line TBL. The touch bridge line TBL can connect any one of the plurality of touch lines TL with a touch sensor TS. The touch bridge line TBL can be connected to any one of the plurality of touch lines TL through a first contact hole CH1. The touch bridge line TBL can be connected to at least two touch sensors TS arranged in the second direction (e.g., X-axis direction) while being extended in the second direction (e.g., X-axis direction). According to an embodiment, the touch bridge line TBL can be connected to a group of two or more touch sensors TS.

In the transparent display panel 110 according to one embodiment of the present disclosure, the plurality of touch lines TL can be disposed in the first non-transmissive area NTA1 that is not the second non-transmissive area NTA2, whereby light transmittance can be prevented from being deteriorated due to the plurality of touch lines TL. The second non-transmissive area NTA2 extended in the second direction (e.g., X-axis direction) crosses between adjacent transmissive areas TA as shown in FIG. 3. When a width of the second non-transmissive area NTA2 crossing the transmissive areas TA is increased, a size of the transmissive area TA is necessarily reduced.

When the plurality of touch lines TL are disposed in the second non-transmissive area NTA2, the width of the second non-transmissive area NTA2 is increased to dispose a large number of lines, and the size of the transmissive area TA is reduced. That is, a problem can occur in that light transmittance of the transparent display panel 110 is reduced due to the plurality of touch lines TL.

In the transparent display panel 110 according to one embodiment of the present disclosure, the plurality of touch lines TL are disposed in the first non-transmissive area NTA1, and only one touch bridge line TBL for connecting the plurality of touch sensors TS is provided in the second non-transmissive area NTA2. Therefore, the transparent display panel 110 according to one embodiment of the present disclosure can reduce or minimize the size decrease of the transmissive area TA or decrease in light transmittance due to the plurality of touch lines TL and the touch bridge line TBL. In other words, more space can be allocated to the transmissive area TA and the transmissive area TA can be less crowded with fewer wiring elements or circuit elements.

The touch sensor TS can be provided in the transmissive area TA. The touch sensor TS can be disposed in each of the plurality of transmissive areas TA, and can experience a change in capacitance during user contact. A touch driver can be connected to the plurality of touch sensors TS through the plurality of touch lines TL to detect a change in capacitance of the plurality of touch sensors TS. The plurality of touch sensors TS can correspond to the plurality of pixels P on a one-to-one basis.

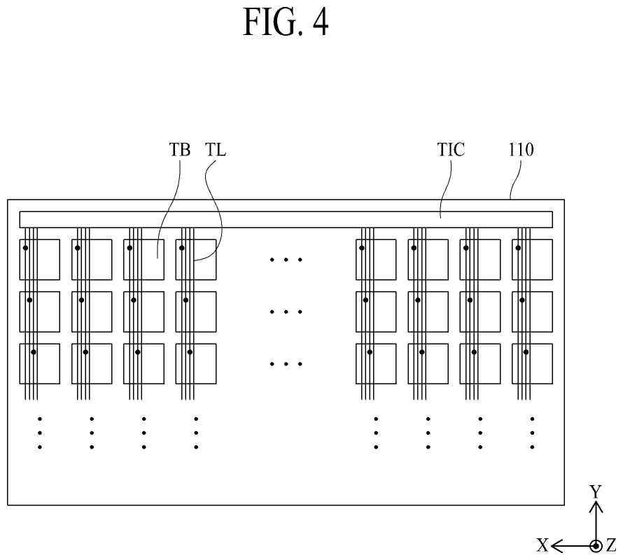

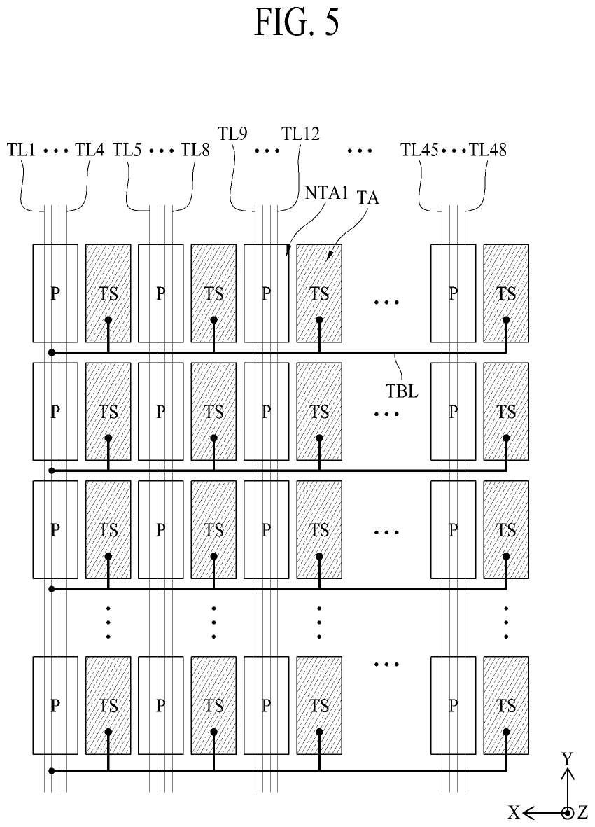

Hereinafter, a connection relation among a plurality of touch sensors TS, a plurality of touch lines TL and a plurality of touch bridge lines TBL will be described in more detail with reference to FIGS. 4 and 5.

FIG. 4 is a view illustrating a connection relationship between a plurality of touch blocks and a plurality of touch lines according to an embodiment, and FIG. 5 is a view illustrating a connection relation between a plurality of touch lines and a plurality of touch sensors in one touch block according to an embodiment.

Referring to FIGS. 4 to 5, the transparent display panel 110 according to one embodiment of the present disclosure can include a plurality of touch blocks TB. Each of the plurality of touch blocks TB can include a plurality of pixels P and a plurality of transmissive areas TA disposed to correspond to the plurality of pixels P one-to-one as a basic unit for determining a user touch position.

The transparent display panel 110 according to one embodiment of the present disclosure can include a plurality of touch sensors TS provided in each the plurality of transmissive areas TA. For example, each of the plurality of touch blocks TB can include 12×20 pixels P and 12×20 touch sensors TS. In this situation, when image resolution is 1920×960, touch resolution can be 160×48.

In the transparent display panel 110 according to one embodiment of the present disclosure, as each of the plurality of touch lines TL is connected to one of the plurality of touch blocks TB, a change in capacitance of the touch sensors TS provided in the connected touch block TB can be sensed. That is, the plurality of touch lines TL provided in the transparent display panel 110 can correspond to the plurality of touch blocks TB on a one-to-one basis. Therefore, the number of touch lines TL can be the same as the number of touch blocks TB in the transparent display panel 110. For example, when the number of touch blocks TB is 160×48, the number of the touch lines TL can also be 160×48, and can be connected to the touch driver TIC.

As described above, in order to form as many touch lines TL as the number of touch blocks TB, at least two touch lines TL should be provided in one first non-transmissive area NTA1. For example, when image resolution is 1920×960 and touch resolution is 160×48, four touch lines TL can be provided in one first non-transmissive area NTA1, as shown in FIG. 3, in order to form 160×48 touch lines TL in the transparent display panel 110.

The plurality of touch sensors TS provided in one touch block TB can be connected to one of the plurality of touch lines TL provided in one touch block TB as shown in FIG. 5. For example, twelve first non-transmissive areas NTA1 can be provided in one touch block TB, and four touch lines TL can be disposed in each of the twelve first non-transmissive areas NTA1. For example, four touch lines TL can be disposed to overlap with a column of first non-transmissive areas NTA1, while a column of transmissive areas TA can be free of any touch lines. As a result, one touch block TB can be provided with 48 touch lines TL1, . . . , TL48. In this situation, the plurality of touch sensors TS provided in one touch block TB can be connected to one specific touch line TL of the 48 touch lines TL1, . . . , TL48. At this time, the specific touch line TL can be connected to the plurality of touch sensors TS arranged in the second direction (e.g., X-axis direction) through the touch bridge lines TBL extended in the second direction (e.g., X-axis direction). As a result, the plurality of touch sensors TS provided in one touch block TB can be electrically connected through the specific touch line TL and the touch bridge lines TBL.

Each of the plurality of touch lines TL can correspond to touch blocks TB on a one-to-one basis. Therefore, the plurality of touch blocks TB are connected to different touch lines TL and thus can be electrically separated from each other. Each touch line TL can connect a plurality of touch sensors TS provided in a corresponding touch block TB to a touch driver TIC. In detail, each touch line TL can transmit the changed capacitance provided from the touch sensors TS provided in the touch block TB to the touch driver TIC. The touch driver TIC can sense the changed capacitance, and can determine a touch position of a user. Also, each touch line TL can provide the touch sensing voltage generated from the touch driver TIC to the touch sensors TS provided in the touch block TB.

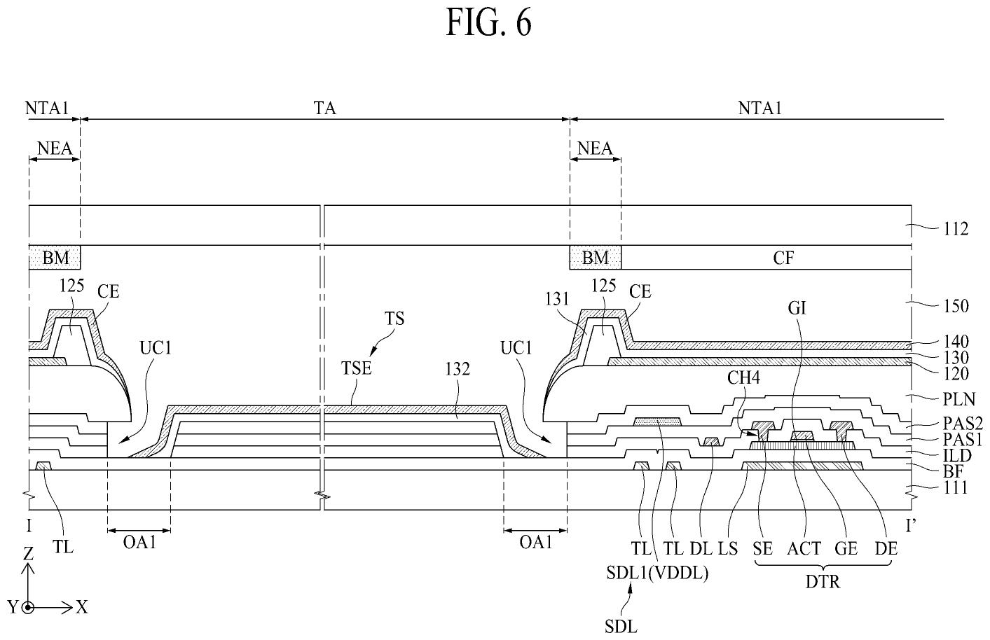

Hereinafter, light emitting elements of a light emission area EA and touch sensors TS of a transmissive area TA will be described in more detail with reference to FIG. 6.

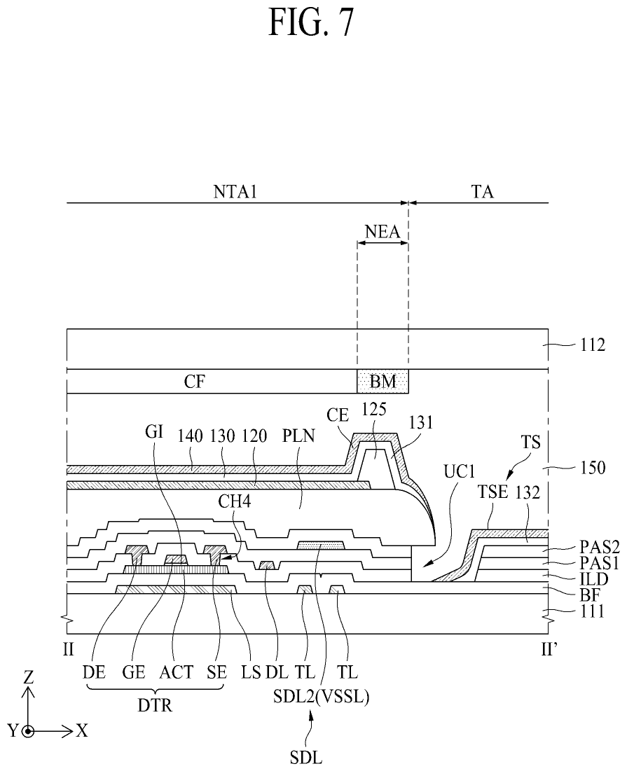

FIG. 6 is a cross-sectional view illustrating an example of line I-I′ of FIG. 3 according to an embodiment, and FIG. 7 is a cross-sectional view illustrating an example of line II-II′ of FIG. 3 according to an embodiment.

Referring to FIGS. 3 and 6, in the transparent display panel 110 according to one embodiment of the present disclosure, the first substrate 111 can include a plurality of transmissive areas TA and a non-transmissive area NTA including a plurality of light emission areas EA disposed between adjacent transmissive areas TA. The non-transmissive area NTA can include a first non-transmissive area NTA1 extended in a first direction (e.g., Y-axis direction) and a second non-transmissive area NTA2 extended in a second direction (e.g., X-axis direction).

The first non-transmissive area NTA1 can include circuit areas CA1, CA2, CA3 and CA4 in which at least one transistor and a capacitor are disposed. In addition, the first non-transmissive area NTA1 can be extended in the first direction (e.g., Y-axis direction), and can include a pixel power line VDDL, a common power line VSSL, a reference line RL, data lines DL, touch lines TL and a sensing line SSL, which are disposed so as not to overlap the circuit areas CA1, CA2, CA3 and CA4. The second non-transmissive area NTA2 can include a scan line SCANL and a touch bridge line TBL, which are extended in the second direction (e.g., X-axis direction).

At least one transistor can include a driving transistor DTR and switching transistors. The switching transistor can be switched in accordance with a scan signal supplied to a scan line SCANL to charge a data voltage supplied from the data line DL in the capacitor.

The driving transistor DTR can be switched in accordance with the data voltage charged in the capacitor to generate a data current from a power source supplied from the pixel power line VDDL and supply the data current to a first electrode layer 120 of subpixels SP1, SP2, SP3 and SP4. The driving transistor DTR can include an active layer ACT, a gate electrode GE, a source electrode SE and a drain electrode DE.

In detail, as shown in FIG. 6, a light-shielding layer LS can be provided over the first substrate 111. The light-shielding layer LS can serve to shield external light incident on the active layer ACT in an area where the driving transistor DTR is formed. The light-shielding layer LS can include a single layer or multi-layer made of any one of molybdenum (Mo), aluminum (Al), chromium (Cr), gold (Au), titanium (Ti), nickel (Ni), neodymium (Nd) and copper (Cu) or their alloy.

In the transparent display panel 110 according to one embodiment of the present disclosure, at least a portion of the pixel power line VDDL, the common power line VSSL, the reference line RL, the data lines DL, the touch lines TL and the touch bridge line TBL can be formed on the same layer as the light-shielding layer LS. For example, the reference line RL and the touch lines TL can be formed of the same material as that of the light-shielding layer LS on the same layer as the light-shielding layer LS and they can be formed during a same manufacturing step, but embodiments are not limited thereto.

A buffer layer BF can be provided over the light-shielding layer LS. The buffer layer BF can protect the driving transistor DTR from moisture permeated through the first substrate 111 vulnerable to moisture permeation, and can include an inorganic layer, for example, a silicon oxide layer (SiOx), a silicon nitride layer (SiNx) or their multi-layer.

The active layer ACT of the driving transistor DTR can be provided over the buffer layer BF. The active layer ACT can include a silicon-based semiconductor material or an oxide-based semiconductor material.

A gate insulating layer GI can be provided over the active layer ACT of the driving transistor DTR. The gate insulating layer GI can be patterned only in an area where the gate electrode GE is disposed. The gate insulating layer GI can include an inorganic layer, for example, a silicon oxide layer (SiOx), a silicon nitride layer (SiNx) or their multi-layer.

The gate electrode GE of the driving transistor DTR can be provided over the gate insulating layer GI. The gate electrode GE can include a single layer or multi-layer made of any one of molybdenum (Mo), aluminum (Al), chromium (Cr), gold (Au), titanium (Ti), nickel (Ni), neodymium (Nd) and copper (Cu) or their alloy.

An interlayer insulating layer ILD can be provided over the gate electrode GE of the driving transistor DTR. The interlayer insulating layer ILD can be provided in the non-transmissive area NTA and the transmissive area TA. However, in order to form a first undercut structure UC1 in the transmissive area TA, the interlayer insulating layer ILD can be provided with a first opening area OA1, which exposes the buffer layer BF, without being provided in at least a portion of the transmissive area TA. The interlayer insulating layer ILD can include an inorganic layer, for example, a silicon oxide layer (SiOx), a silicon nitride layer (SiNx) or their multi-layer.

A source electrode SE and a drain electrode DE of the driving transistor DTR can be disposed over the interlayer insulating layer ILD. The source electrode SE and the drain electrode DE of the driving transistor DTR can be connected to the active layer ACT of the driving transistor DTR through a fourth contact hole CH4 passing through the interlayer insulating layer ILD. The source electrode SE and the drain electrode DE can include a single layer or multi-layer made of any one of molybdenum (Mo), aluminum (Al), chromium (Cr), gold (Au), titanium (Ti), nickel (Ni), neodymium (Nd) and copper (Cu) or their alloy.

In the transparent display panel 110 according to one embodiment of the present disclosure, at least a portion of the pixel power line VDDL, the common power line VSSL, the reference line RL, the data lines DL, the touch lines TL and the touch bridge line TBL can be provided on the same layer as the source electrode SE and the drain electrode DE of the driving transistor DTR. For example, the data lines DL can include the same material on the same layer as the source electrode SE and the drain electrode DE and can be made during a same processing step, but embodiments are not limited thereto.

A first passivation layer PAS1 can be provided over the source electrode SE and the drain electrode DE of the driving transistor DTR for insulating the driving transistor DTR, and a second passivation layer PAS2 can be provided over the first passivation layer PAS1.

The first and second passivation layers PAS1 and PAS2 can be provided in the non-transmissive area NTA and the transmissive area TA. However, in order to form the first undercut structure UC1 in the transmissive area TA, the first and second passivation layers PAS1 and PAS2 can be provided with a first opening area OA1, which exposes the buffer layer BF, without being provided in at least a portion of the transmissive area TA (e.g., a hole can made through the first and second passivation layers PAS1 and PAS2 or removed area). The first opening area OA1 of the first and second passivation layers PAS1 and PAS2 can overlap with the first opening area OA1 of the interlayer insulating layer ILD (e.g., a hole can extend all the way through ILD, PAS1 and PAS2). The first and second passivation layers PAS1 and PAS2 can include an inorganic layer, for example, a silicon oxide layer (SiOx), a silicon nitride layer (SiNx) or their multi-layer.

A shielding layer SDL can be provided between the first and second passivation layers PAS1 and PAS2 (e.g., SDL can be sandwiched between PAS1 and PAS2). The shielding layer SDL can be extended in the first direction (e.g., Y-axis direction) on the touch lines TL along the touch lines TL. The shielding layer SDL can be provided to at least partially overlap with the touch lines TL. Also, a center line of the shielding layer SDL can be positioned over a center line between a pair of touch lines TL, but embodiments are not limited thereto.

A plurality of shielding layers SDL can be provided, and each of the shielding layers SDL can be provided to overlap with at least one or more of the plurality of touch lines TL. At least one touch line TL can be disposed in each of at least two areas spaced apart from each other. In this situation, the shielding layer SDL can be provided in each of the at least two areas (e.g., the shielding layer SDL can overlap with a pair of adjacent touch lines TL). At this time, one shielding layer SDL can overlap with one touch line TL while having a width covering one touch line TL. Alternatively, one shielding layer SDL can overlap two or more touch lines TL while having a width covering two or more touch lines TL.

For example, in one first non-transmissive area NTA1, two first touch lines TL can be disposed between the circuit area CA1, CA2, CA3 and CA4 and the transmissive area TA disposed at a left side of the circuit areas CA1, CA2, CA3 and CA4. Two second touch lines TL can be disposed between the circuit areas CA1, CA2, CA3 and CA4 and the transmissive area TA disposed at a right side of the circuit areas CA1, CA2, CA3 and CA4.

In this situation, the shielding layer SDL can include a first shielding layer SDL1 and a second shielding layer SDL2. As shown in FIGS. 3 and 6, the first shielding layer SDL1 can be provided over two first touch lines TL disposed between the circuit areas CA1, CA2, CA3 and CA4 and the transmissive area TA disposed at the left side of the circuit areas CA1, CA2, CA3 and CA4. The first shielding layer SDL1 can be provided to overlap with two first touch lines TL while having a width covering two first touch lines TL.

The second shielding layer SDL2 can be disposed to be spaced apart from the first shielding layer SDL1, and can be provided on two second touch lines TL disposed between the circuit areas CA1, CA2, CA3 and CA4 and the transmissive area TA disposed at the right side of the circuit area CA1, CA2, CA3 and CA4 as shown in FIGS. 3 and 7. The second shielding layer SDL2 can be provided to overlap with two second touch lines TL while having a width that covers the two second touch lines TL.

In one embodiment, the first shielding layer SDL1 and the second shielding layer SDL2 can include a conductive material. The first shielding layer SDL1 and the second shielding layer SDL2 can include a single layer or multi-layer made of any one of molybdenum (Mo), aluminum (Al), chromium (Cr), gold (Au), titanium (Ti), nickel (Ni), neodymium (Nd), copper (Cu) and ITO, or their alloy. For example, the first shielding layer SDL1 and the second shielding layer SDL2 can include an alloy of molybdenum (Mo) and titanium (Ti) or a stacked structure of an alloy of molybdenum (Mo) and titanium (Ti) and ITO.

In one embodiment, the first shielding layer SDL1 and the second shielding layer SDL2 can be power lines for supplying a power source to the subpixels SP1, SP2, SP3 and SP4. Each of the first shielding layer SDL1 and the second shielding layer SDL2 can be one of the pixel power line VDDL and the common power line VSSL. For example, the first shielding layer SDL1 can be the pixel power line VDDL for supplying a first power source to the driving transistor DTR of each of the subpixels SP1, SP2, SP3 and SP4. The second shielding layer SDL2 can be the common power line VSSL for supplying a second power source to a cathode electrode of the subpixels SP1, SP2, SP3 and SP4.

In the transparent display panel 110 according to one embodiment of the present disclosure, at least a portion of the pixel power line VDDL, the common power line VSSL, the reference line RL, the data lines DL, the touch lines TL and the touch bridge line TBL can be formed on the same layer as the shielding layer SDL, include a same material and be formed during a same manufacturing step.

A planarization layer PLN for planarizing a step difference due to the driving transistor DTR and the plurality of signal lines can be provided over the second passivation layer PAS2. The planarization layer PLN can be provided in the non-transmissive area NTA and may not be provided in at least a portion of the transmissive area TA. The planarization layer PLN can suppress transparency by inducing refraction or the like of light while transmitting light. Therefore, the transparent display panel 110 according to one embodiment of the present disclosure can increase transparency by removing a portion of the planarization layer PLN in the transmissive area TA. The planarization layer PLN can include an organic layer, such as acryl resin, epoxy resin, phenolic resin, polyamide resin, polyimide resin or the like.

In the transparent display panel 110 according to one embodiment of the present disclosure, the first undercut structure UC1 can be formed using the planarization layer PLN and a plurality of inorganic insulating layers, for example, the first and second passivation layers PAS1 and PAS2 and the interlayer insulating layer ILD. For example, an overhang portion or an eave portion formed at an outer edge of the planarization layer PLN can block a shaded area on the buffer layer BF from receiving part of the second electrode layer 140. For example, a type of trench or moat can be formed around each touch sensor TS. Further in this example, a large cathode layer can be laid down across the panel which can be effectively cut or split into different cathode portions by the overhang portion of the planarization layer PLN working together with a trench extending through the interlayer insulating layer ILD and the first and second passivation layers PAS1 and PAS2. In this way, the cathode layer 140 can be divided into portions for touch sensors and portions for cathode electrodes for the subpixels. Also, the touch sensor electrode TSE and the cathode layer 140 for the subpixels can be formed at a same time during the same manufacturing step and from a same material.

In detail, the first undercut structure UC1 can be formed in such a manner that the planarization layer PLN protrudes out further than the plurality of insulating layers, for example, the first and second passivation layers PAS1 and PAS2, the interlayer insulating layer ILD and the gate insulating layer GI in a direction of the transmissive area TA (e.g., PLN can include an overhang portion or an eave portion). Therefore, the first undercut structure UC1 can expose at least a portion of a lower surface of the planarization layer PLN, and can form a space from the buffer layer BF without being provided with the plurality of inorganic layers below the exposed lower surface. For example, an empty space can be formed between an upper surface of the buffer layer BF and a lower surface of the planarization layer PLN (e.g., UC1).

The first undercut structure UC1 can be provided in the transmissive area TA. In more detail, the first undercut structure UC1 can be provided between the touch sensor TS and the non-transmissive area NTA. In addition, the first undercut structure UC1 can have a closed loop shape in a plane view. As an example, the first undercut structure UC1 can be formed along an entire edge area of the transmissive area TA. In this situation, the first undercut structure UC1 can be formed to surround all the way around the touch sensor TS.

In the transparent display panel 110 according to one embodiment of the present disclosure, the first undercut structure UC1 can be formed using the planarization layer PLN and the plurality of inorganic insulating layers made of a transparent material, whereby light transmittance can be improved due to the first undercut structure UC1 since the light has fewer portions to pass through.

The first electrode layer 120, an organic light emitting layer 130, a second electrode layer 140 and a bank 125 can be provided over the planarization layer PLN.

The first electrode layer 120 can be provided for each of the subpixel SP1, SP2, SP3 and SP4 on the planarization layer PLN. The first electrode layer 120 is not provided in the transmissive area TA. The first electrode layer 120 can be connected to the driving transistor DTR. In detail, the first electrode layer 120 can be connected to one of the source electrode SE and the drain electrode DE of the driving transistor DTR through a contact hole passing through the planarization layer PLN and the first and second passivation layers PAS1 and PAS2.

The first electrode layer 120 can include a metal material having high reflectance such as a stacked structure (Ti/Al/Ti) of aluminum and titanium, a stacked structure (ITO/Al/ITO) of aluminum and ITO, Ag alloy, a stacked structure (ITO/Ag alloy/ITO) of Ag alloy and ITO, MoTi alloy, and a stacked structure (ITO/MoTi alloy/ITO) of MoTi alloy and ITO. The Ag alloy can be an alloy of silver (Ag), palladium (Pd) and copper (Cu). The MoTi alloy can be an alloy of molybdenum (Mo) and titanium (Ti). The first electrode layer 120 can be an anode electrode of a light emitting element.

The bank 125 can be provided over the planarization layer PLN. In addition, the bank 125 can be formed to at least partially cover an edge of the first electrode layer 120 and expose a portion of the first electrode layer 120. Therefore, the bank 125 can prevent emission efficiency from being deteriorated due to concentration of a current on an end portion of the first electrode layer 120.

The bank 125 can define light emission areas EA1, EA2, EA3 and EA4 of the subpixels SP1, SP2, SP3 and SP4. The light emission areas EA1, EA2, EA3 and EA4 of the subpixels SP1, SP2, SP3 and SP4 represent areas in which the first electrode layer 120, the organic light emitting layer 130 and a cathode electrode CE are sequentially stacked so that holes from the first electrode layer 120 and electrons from the cathode electrode CE are combined with each other in the organic light emitting layer 130 to emit light. In this situation, the area in which the bank 125 is formed can become a non-light emission area NEA because light is not emitted therefrom, and the area in which the bank 125 is not formed and the first electrode layer 120 is exposed can become the light emission area EA. The bank 125 can include an organic layer such as acryl resin, epoxy resin, phenolic resin, polyamide resin, and polyimide resin.

The organic light emitting layer 130 can be provided over the first electrode layer 120. The organic light emitting layer 130 can include a hole transporting layer, a light emitting layer and an electron transporting layer. In this situation, when a voltage is applied to the first electrode layer 120 and the cathode electrode CE, holes and electrons move to the light emitting layer through the hole transporting layer and the electron transporting layer, respectively, and are combined with each other in the light emitting layer to emit light.

In one embodiment, the organic light emitting layer 130 can be a common layer commonly formed in the subpixels SP1, SP2, SP3 and SP4. In this situation, the light emitting layer can be a white light emitting layer for emitting white light.

In another embodiment, the light emitting layer of the organic light emitting layer 130 can be individually formed for each of the subpixels SP1, SP2, SP3 and SP4. For example, a green light emitting layer for emitting green light can be formed in the first subpixel SP1, a red light emitting layer for emitting red light can be formed in the second subpixel SP2, a blue light emitting layer for emitting blue light can be formed in the third subpixel SP3, and a white light emitting layer for emitting white light can be formed in the fourth subpixel SP4. In this situation, the light emitting layer of the organic light emitting layer 130 is not formed in the transmissive area TA.

The organic light emitting layer 130 can be separated and disconnected in an area between the non-transmissive area NTA and the transmissive area TA by the first undercut structure UC1. In detail, the organic light emitting layer 130 can be divided into an organic light emitting layer 131 provided in the non-transmissive area NTA and an organic light emitting layer 132 provided in the transmissive area TA by the first undercut structure UC1. That is, the organic light emitting layer 131 of the organic light emitting layer 130, which is provided in the non-transmissive area NTA, and the organic light emitting layer 132 of the organic light emitting layer 130, which is provided in the transmissive area TA, can be spaced apart from each other by the first undercut structure UC1.

The second electrode layer 140 can be provided over the organic light emitting layer 130 and the bank 125. When the second electrode layer 140 is deposited on the entire surface, the second electrode layer 140 can be separated without being continuous between the non-transmissive area NTA and the transmissive area TA by the first undercut structure UC1. In detail, the second electrode layer 140 can be divided into a second electrode CE provided in the non-transmissive area NTA and a second electrode TSE provided in the transmissive area TA by the first undercut structure UC1 (e.g., two different types of electrodes can be formed by dividing/cutting the second electrode layer 140 into different portions via the first undercut structure UC1).

The portion of the second electrode CE provided in the non-transmissive area NTA is the cathode electrode (hereinafter, referred to as ‘cathode electrode CE’), and can be an element constituting the light emitting element. The cathode electrode CE can be connected to a cathode contact electrode CCT to receive a power source from the common power line VSSL. The cathode electrode CE can be a common layer that is commonly formed in the subpixels SP1, SP2, SP3 and SP4 to apply the same voltage to the subpixels.

The portion of the second electrode TSE provided in the transmissive area TA is a touch sensor electrode TSE (hereinafter, referred to as ‘touch sensor electrode TSE’), and can be an element constituting the touch sensor TS. The touch sensor electrode TSE can be connected to a touch contact electrode TCT to provide a change in capacitance to the touch line TL.

In detail, the touch sensor TS can be connected to the touch line TL through the touch contact electrode TCT and the touch bridge line TBL.

The touch bridge line TBL can connect the touch contact electrode TCT with the touch line TL. The touch bridge line TBL can include a first touch bridge line TBL1, a second touch bridge line TBL2 and a third touch bridge line TBL3 as shown in FIG. 3.

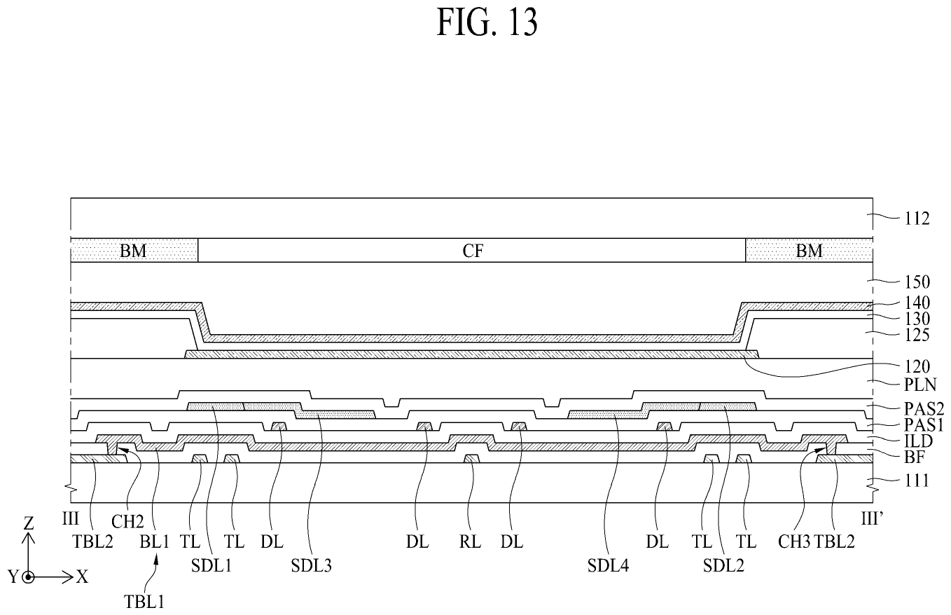

The first touch bridge line TBL1 can be disposed in an area where the first non-transmissive area NTA1 and the second non-transmissive area NTA2 cross each other, and can be extended in the second direction (e.g., X-axis direction). One end of the first touch bridge line TBL1 can be connected to one second touch bridge line TBL2 through one second contact hole CH2, and the other end of the first touch bridge line TBL1 can be connected to another second touch bridge line TBL2 through a third contact hole CH3 (e.g., see FIG. 13). The first touch bridge line TBL1 can be connected to one of the plurality of touch lines TL through a first contact hole CH1.

The first touch bridge line TBL1 can be disposed on a layer different from first signal lines SL1 extended in the first direction (e.g., Y-axis direction) in the first non-transmissive area NTA1. The first touch bridge line TBL1 can be disposed on the same layer as at least one of the light-shielding layer LS, the active layer ACT, the gate electrode GE, the source electrode SE or the drain electrode DE of the driving transistor DTR. For example, the first touch bridge line TBL1 can be disposed on the same layer as the gate electrode GE of the driving transistor DTR and made of a same material and made during a same processing step, but embodiments are not limited thereto.

In one embodiment, the first touch bridge line TBL1 can include a first branch line BL1 and a second branch line BL2 as shown in FIG. 3. The first touch bridge line TBL1 can be branched to the first branch line BL1 and the second branch line BL2 at one side, and then the first branch line BL1 and the second branch line BL2 can be connected to each other at the other side.

Since the first touch bridge line TBL1 is disposed in an area crossing the first signal lines SL1, the first touch bridge line TBL1 can be disposed to be adjacent to at least one of the first signal lines SL1 in a vertical direction. For example, the first touch bridge line TBL1 can be disposed on the same layer as the gate electrode GE of the driving transistor DTR, and data lines DL can be disposed on the same layer as the source electrode SE and the drain electrode DE of the driving transistor DTR. When particles flow into the first touch bridge line TBL1 and the data lines DL, which are disposed to be adjacent to each other in the vertical direction, during the process, the first touch bridge line TBL1 and the data lines DL can be connected to each other to generate a short circuit. In this situation, since a touch signal cannot be applied to the plurality of touch sensors TS connected to the first touch bridge line TBL1, the plurality of touch sensors TS cannot operate normally.

In the transparent display panel 110 according to one embodiment of the present disclosure, the first touch bridge line TBL1 can be formed of the first branch line BL1 and the second branch line BL2 in order to reduce a defect rate of the touch sensor TS. When any one of the first branch line BL1 and the second branch line BL2 generates a short circuit with another signal line, in the transparent display panel 110 according to one embodiment of the present disclosure, the branch line in which short circuit occurs can be cut by laser. In this way, redundant lines can be provided which can be sacrificed if needed, without affecting the touch sensing functions. Therefore, the touch sensors TS can receive a signal from the touch line TL through the branch line in which no short circuit occurs, whereby the touch sensors TS can operate normally.

The second touch bridge line TBL2 can be provided in the second non-transmissive area NTA2 disposed between the transmissive areas TA. The second touch bridge line TBL2 can be electrically connected to the first touch bridge line TBL 1 and then can be extended in the second direction (e.g., X-axis direction). In detail, one end of the second touch bridge line TBL2 can be connected to one first touch bridge line TBL1 through one second contact hole CH2, and the other end of the second touch bridge line TBL2 can be connected to the other first touch bridge line TBL1 through a third contact hole CH3.

The second touch bridge line TBL2 can be disposed on the same layer as at least one of the light-shielding layer LS, the active layer ACT, the gate electrode GE, the source electrode SE or the drain electrode DE of the driving transistor DTR. For example, the second touch bridge line TBL2 can be disposed on the same layer as the light-shielding layer LS.

The third touch bridge line TBL3 can electrically connect the touch contact electrode TCT with the second touch bridge line TBL2. The third touch bridge line TBL3 can be protruded from one side of the second touch bridge line TBL2 and extended to an area overlapped with the touch sensor TS. The third touch bridge line TBL3 can be electrically connected to the touch contact electrode TCT at one end.

The third touch bridge line TBL3 can be formed on a layer provided between the first substrate 111 and the driving transistor DTR. In one embodiment, the third touch bridge line TBL3 can be formed of the same material as that of the light-shielding layer LS on the same layer as the light-shielding layer LS. The third touch bridge line TBL3 can be extended across the first undercut structure UC1. The first undercut structure UC1 can be formed through wet etching processes. In the transparent display panel 110 according to one embodiment of the present disclosure, the third touch bridge line TBL3 can be formed on the same layer as the light-shielding layer LS so that the third touch bridge line TBL3 can be prevented from being lost during the wet etching process for forming the first undercut structure UC1.

The third touch bridge line TBL3 can be formed on the same layer as the second touch bridge line TBL2, but is not necessarily limited thereto. The third touch bridge line TBL3 can be formed in a layer different from the second touch bridge line TBL2. However, even in this situation, it can be desirable for the third touch bridge line TBL3 to be formed on a layer provided between the first substrate 111 and the driving transistor DTR.

The touch contact electrode TCT can be provided in the transmissive area TA. The touch contact electrode TCT can be disposed between the third touch bridge line TBL3 and the touch sensor electrode TSE to electrically connect the third touch bridge line TBL3 with the touch sensor electrode TSE. The touch contact electrode TCT can be connected to the third touch bridge line TBL3 through a contact hole.

Also, at least a portion of an upper surface of the touch contact electrode TCT can be exposed by the second undercut structure, and the touch sensor electrode TSE can be connected to the exposed upper surface. In detail, the touch contact electrode TCT can be formed on a layer provided between the buffer layer BF and the second passivation layer PAS2. In one embodiment, the touch contact electrode TCT can be provided between the interlayer insulating layer ILD and the first passivation layer PAS1. That is, the touch contact electrode TCT can be provided on the same layer as the source electrode SE and the drain electrode DE of the driving transistor DTR.

In this situation, the first and second passivation layers PAS1 and PAS2 can be provided with an opening area that exposes at least a portion of the upper surface of the touch contact electrode TCT. Therefore, the touch sensor electrode TSE can be connected to the exposed upper surface of the touch contact electrode TCT, so that the touch contact electrode TCT can be electrically connected to the touch sensor electrode TSE. As a result, the touch sensor electrode TSE can be electrically connected to the touch line TL through the touch contact electrode TCT and the touch bridge line TBL.

The second electrode layer 140, which includes the cathode electrode CE and the touch sensor electrode TSE, can include a transparent conductive material (TCO) such as ITO and IZO, which can transmit light, or a semi-transmissive conductive material such as magnesium (Mg), silver (Ag) or an alloy of magnesium (Mg) and silver (Ag). When the second electrode layer 140 is formed of a semi-transmissive conductive material, light emitting efficiency can be increased by formation of a micro cavity.

An encapsulation layer can be provided on the light emitting elements and the touch sensors TS. The encapsulation layer can be formed to cover the cathode electrode CE and the touch sensor electrode TSE on the cathode electrode CE and the touch sensor electrode TSE. The encapsulation layer serves to prevent oxygen or moisture from being permeated into the organic light emitting layer 130, the cathode electrode CE and the touch sensor electrode TSE. Accordingly, in some embodiments, the encapsulation layer can include at least one inorganic layer and at least one organic layer.

A color filter CF can be provided over one surface of a second substrate 112, which faces the first substrate 111. In this situation, the first substrate 111 provided with the light emitting elements and the touch sensors TS and the second substrate 112 provided with the color filter CF can be bonded to each other by a filler 150. At this time, the filler 150 can be made of an organic material having adhesive property, and can be, for example, an optically clear resin layer (OCR).

The color filter CF can be formed to be patterned for each of the subpixels SP1, SP2, SP3 and SP4. A black matrix BM can be provided between the color filters CF. The black matrix BM can be provided between the subpixels SP1, SP2, SP3 and SP4 to prevent color mixture from occurring between adjacent subpixels SP1, SP2, SP3 and SP4, and light incident from the outside can be prevented from being reflected toward the plurality of lines provided between the adjacent subpixels SP1, SP2, SP3 and SP4, for example, the scan lines SCANL, the data lines DL, the pixel power lines VDDL, the common power lines VSSL, the reference lines RL, the touch lines TL, the touch bridge line TBL, etc. Also, the black matrix BM can be disposed to overlap with the bank 125.

In the transparent display panel 110 according to one embodiment of the present disclosure, the touch sensor electrode TSE of the touch sensor TS and the cathode electrode CE of the light emitting element can be formed on the same layer, from the same material and during a same manufacturing processing step, by using the first undercut structure UC1 to divide cathode layer 140 into different portions. In the transparent display panel 110 according to one embodiment of the present disclosure, a touch manufacturing process can be simplified, and a separate mask for the touch sensor electrode TSE is not required additionally. Therefore, the transparent display panel 110 according to one embodiment of the present disclosure can implement process optimization, reduce production energy and improve yields.

Also, in the transparent display panel 110 according to one embodiment of the present disclosure, the first undercut structure UC1 can be formed using the planarization layer PLN and the plurality of inorganic insulating layers, so that the first undercut structure UC1 can be formed without loss of light transmittance.

Also, in the transparent display panel 110 according to one embodiment of the present disclosure, the touch lines TL can be disposed below the light emitting element, so that emission efficiency of the pixel P can be prevented from being deteriorated due to the touch lines TL.

Also, in the transparent display panel 110 according to one embodiment of the present disclosure, the touch lines TL can be disposed so as not to overlap the circuit areas CA1, CA2, CA3 and CA4, whereby influence due to a circuit element can be minimized and at the same time uniformity of parasitic capacitance can be improved.

Also, in the transparent display panel 110 according to one embodiment of the present disclosure, the plurality of touch lines TL can be disposed in the first non-transmissive area NTA1, and only one touch bridge line TBL for connecting the plurality of touch sensors TS can be provided in the second non-transmissive area NTA2, whereby reduction in a size of the transmissive area TA or light transmittance due to the plurality of touch lines TL and the touch bridge line TBL can be minimized.

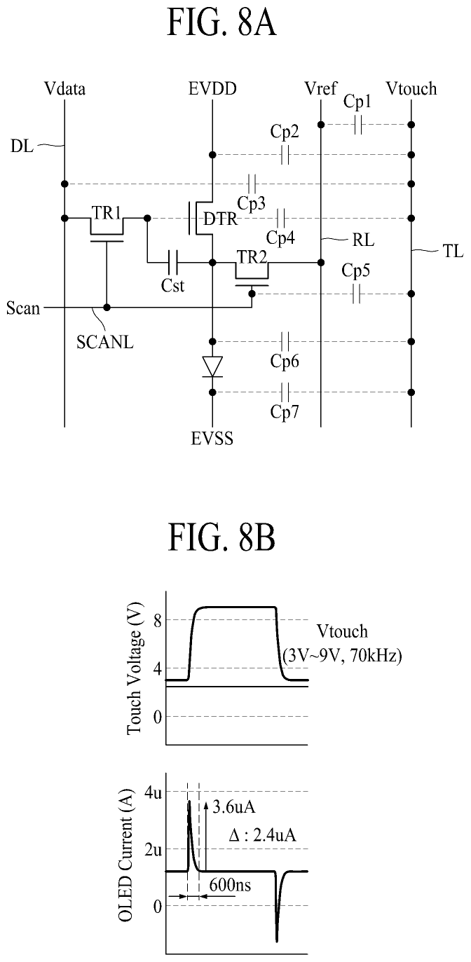

In the transparent display panel 110 according to one embodiment of the present disclosure, since the plurality of touch lines TL should be disposed in the first non-transmissive area NTA1 having a small size, the touch lines TL are provided below the light emitting element to overlap with the first electrode layer 120 of the light emitting element and are disposed to be adjacent to the other signal lines SL1 and SL2. Also, the power line VDDL can be disposed between first electrode layer 120 of the light emitting element and the touch lines TL to save even more space. Therefore, parasitic capacitance can be generated among the touch lines TL, the first electrode layer 120 of the light emitting element and the other signal lines SL1 and SL2. The parasitic capacitance among the touch lines TL, the first electrode layer 120 of the light emitting element and the other signal lines SL1 and SL2 can affect a touch recognition rate. Hereinafter, the parasitic capacitance generated among the touch lines TL, the first electrode layer 120 of the light emitting element and the other signal lines SL1 and SL2 will be described with reference to FIGS. 8A and 8B.

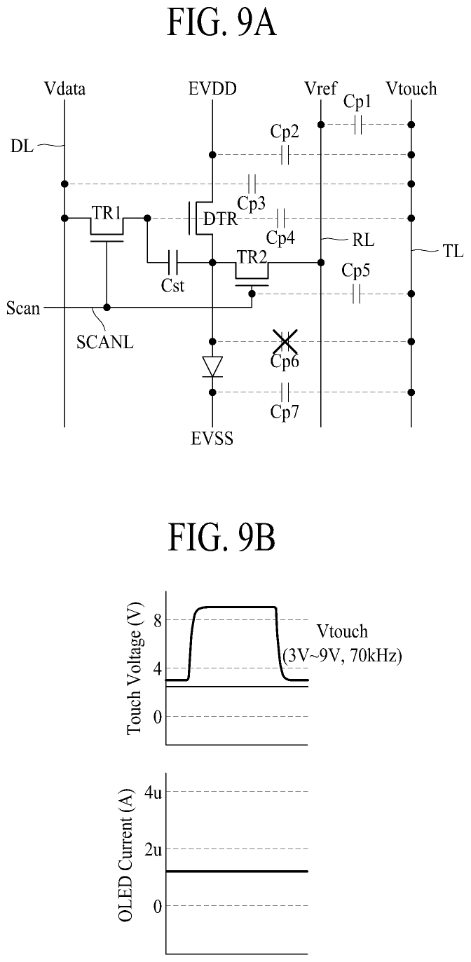

FIG. 8A is a circuit view illustrating parasitic capacitance generated between a touch line and signal lines, and FIG. 8B is a view illustrating an influence of a touch signal on a light emitting element. FIG. 9A is a circuit view illustrating parasitic capacitance when a shielding layer is provided between a touch line and an anode electrode of a light emitting element, and FIG. 9B is a circuit view illustrating an influence of a touch signal on a light emitting element when a shielding layer is provided between a touch line and an anode electrode of a light emitting element.

Referring to FIG. 8A, the transparent display panel 110 according to one embodiment of the present disclosure can include a circuit element consisting of first and second switching transistors TR1 and TR2, a driving transistor DTR, a capacitor Cst and a light emitting element OLED. The first and second switching transistors TR1 and TR2, the driving transistor DTR, the capacitor Cst and the light emitting element OLED can be provided for each of the subpixels SP1, SP2, SP3 and SP4

The first switching transistor TR1 charges a data voltage Vdata supplied from the data line DL in the capacitor Cst. For example, a gate electrode of the first switching transistor TR1 can be connected to a scan line SCANL, and a first electrode of the first switching transistor TR1 connected to a data line DL. A second electrode of the first switching transistor TR1 can be connected to one end of the capacitor Cst and the gate electrode GE of the driving transistor DTR. The first switching transistor TR1 can be turned on in response to a scan signal Scan applied through the scan line SCANL. When the first switching transistor TR1 is turned on, the data voltage Vdata applied through the data line DL can be transferred to one end of the capacitor Cst.

A gate electrode of the second switching transistor TR2 can be connected to the scan line SCANL, and a first electrode of the second switching transistor TR2 can be connected to the reference line RL. In addition, a second electrode of the second switching transistor TR2 can be connected to the source electrode SE of the driving transistor DTR and the other end of the capacitor Cst.

The second switching transistor TR2 can be turned on in response to the scan signal Scan applied through the scan line SCANL. When the second switching transistor TR2 is turned on, a reference voltage Vref applied through the reference line RL can be transferred to the other end of the capacitor Cst. In addition, the reference voltage Vref can be applied to the source electrode SE of the driving transistor DTR.

The driving transistor DTR serves to generate a data current from a first power source EVDD supplied from the pixel power line VDDL and supply the data current to the first electrode layer 120 of the subpixels SP1, SP2, SP3 and SP4. In detail, the gate electrode GE of the driving transistor DTR can be connected to one end of the capacitor Cst, and the drain electrode DE of the driving transistor DTR can be connected to the pixel power line VDDL. In addition, the source electrode SE of the driving transistor DTR can be connected to the first electrode layer 120 of the light emitting element OLED, that is, the anode electrode.

The driving transistor DTR can be turned on in accordance with the data voltage charged in the capacitor Cst. When the driving transistor DTR is turned on, the first power source EVDD applied through the pixel power line VDDL can be transferred to the anode electrode 120 of the light emitting element OLED.

The anode electrode 120 can be connected to the source electrode SE of the driving transistor DTR, and the cathode electrode CE can be connected to the common power line VSSL. The light emitting element OLED can emit light in response to a driving current generated by the driving transistor DTR.

The first and second switching transistors TR1 and TR2, the driving transistor DTR and the capacitor Cst, which are described above, can be disposed in each of the circuit areas CA1, CA2, CA3 and CA4 of the first non-transmissive area NTA1. The light emitting elements OLEDs can be disposed to overlap with the corresponding circuit areas CA1, CA2, CA3 and CA4 in the first non-transmissive area NTA1.

Each of the plurality of touch lines TL is disposed in the first non-transmissive area NTA1, and thus can be disposed to be adjacent to the first and second switching transistors TR1 and TR2, the driving transistor DTR and the signal lines SL1 and SL2 for applying a signal to the capacitor Cst. As shown in FIG. 8A, each touch line TL can generate a plurality of parasitic capacitances with the signal lines SL1 and SL2 and the anode electrode 120 of the light emitting element.

In detail, a first parasitic capacitance Cp1 can occur between the touch line TL and the reference line RL, a second parasitic capacitance Cp2 can occur between the touch line TL and the pixel power line VDDL, and a third parasitic capacitance Cp3 can occur between the touch line TL and the data lines DL. In addition, a fourth parasitic capacitance Cp4 can occur between the touch line TL and the capacitor Cst, a fifth parasitic capacitance Cp5 can occur between the touch line TL and the scan line SCANL, a sixth parasitic capacitance Cp6 can occur between the touch line TL and the anode electrode 120 of the light emitting element OLED, and a seventh parasitic capacitance Cp7 can occur between the touch lint TL and the common power lines VSSL.

The touch line TL can generate parasitic capacitances Cp1, . . . , Cp7 with the plurality of signal lines RL, VDDL, DL, SCANL and VSSL and the light emitting element OLED, and due to the parasitic capacitance, a touch recognition rate can be degraded or impaired. Also, an unstable current can occur in the light emitting element due to the parasitic capacitance Cp6 generated between the anode electrode 120 and the touch line TL.

In detail, a touch sensing voltage Vtouch generated from the touch driver TIC can be applied to the touch line TL. Referring to FIG. 8B, it is noted that at a period at which the touch sensing voltage Vtouch applied to the touch line TL is changed from 3V to 9V, the current flowing in the light emitting element OLED is increased from 1.2 μA to 3.6 μA by the parasitic capacitance existing between the light emitting element OLED and the touch line TL. On the contrary, it is noted that at a period at which the touch sensing voltage Vtouch applied to the touch line TL is changed from 9V to 3V, the current flowing in the light emitting element OLED is reduced from 1.2 μA to −1.2 μA by the parasitic capacitance existing between the light emitting element OLED and the touch line TL.

As shown in FIG. 8B, when the parasitic capacitance exists between the light emitting element OLED and the touch line TL, the current flowing in the light emitting element OLED can be increased or reduced whenever a change occurs in the touch sensing voltage Vtouch applied to the touch line TL. For this reason, a luminance deviation occurs in the light emitting element OLED, and flickering due to the luminance deviation can be visible to a viewer which can impair the user's viewing experience.

In the transparent display panel 110 according to one embodiment of the present disclosure, the plurality of touch lines TL can be provided on the same layer as the light-shielding layer LS, thereby making sure of a maximum distance from the anode electrode 120 of the light emitting element OLED. For example, as shown in FIG. 7, the plurality of touch lines TL can be spaced far away from the anode electrode 120 with six other layers disposed therebetween.

Moreover, the transparent display panel 110 according to one embodiment of the present disclosure can include a shielding layer SDL disposed between the plurality of touch lines TL and the anode electrode 120 of the light emitting element OLED. Therefore, as shown in FIG. 9A, the transparent display panel 110 according to one embodiment of the present disclosure can block or minimize occurrence of the parasitic capacitance Cp6 between the plurality of touch lines TL and the anode electrode 120 of the light emitting element OLED.

In this situation, in the transparent display panel 110 according to one embodiment of the present disclosure, as the parasitic capacitance Cp6 is reduced between the plurality of touch lines TL and the anode electrode 120 of the light emitting element OLED, a touch recognition rate can be improved. Also, as the parasitic capacitance Cp6 generated between the anode electrode 120 and the touch line TL is reduced, a current can stably occur in the light emitting element OLED.

In the transparent display panel 110 according to one embodiment of the present disclosure, it is noted that the current flowing in the light emitting element OLED is constant to be 1.2 μA even at a period at which the touch sensing voltage Vtouch applied to the touch line TL is changed from 3V to 9V or from 9V to 3V as shown in FIG. 9B. Therefore, the transparent display panel 110 according to one embodiment of the present disclosure can prevent flickering caused by a luminance deviation from occurring.

Also, in the transparent display panel 110 according to one embodiment of the present disclosure, the shielding layer SDL can be used as the pixel power line VDDL or the common power line VSSL. Therefore, in the transparent display panel 110 according to one embodiment of the present disclosure, since the shielding layer SDL, the pixel power line VDDL and the common power line VSSL do not need to be provided in a separate layer or area, the shielding layer SDL can be provided without increasing the size of the first non-transmissive area NTA1. As a result, the transparent display panel 110 according to one embodiment of the present disclosure can include the shielding layer SDL without loss of light transmittance.

Also, in the transparent display panel 110 according to one embodiment of the present disclosure, the shielding layer SDL includes a first shielding layer SDL1 and a second shielding layer SDL2, and each of the first shielding layer SDL1 and the second shielding layer SDL2 can be used as the pixel power line VDDL and the common power line VSSL. In this situation, in the transparent display panel 110 according to one embodiment of the present disclosure, a first power source can be applied to the first shielding layer SDL1, and a second power source can be applied to the second shielding layer SDL2. In the transparent display panel 110 according to one embodiment of the present disclosure, since a constant voltage is applied to the first and second shielding layers SDL1 and SDL2, parasitic capacitance generated between the first and second shielding layers SDL1 and SDL2 and the plurality of touch lines TL can be predicted, thereby facilitating touch control. In addition, the transparent display panel 110 according to one embodiment of the present disclosure can reduce touch driving noise. For example, the OLED driving current can remain stable as shown in FIG. 9B, in comparison to the OLED driving current in FIG. 8B.

Unlike the above example, when the first and second shielding layers SDL1 and SDL2 are in a floating state, voltages of the first and second shielding layers SDL1 and SDL2 can be changed due to their peripheral signal lines and circuit elements, and the changed voltages cannot be predicted. In this situation, since it is difficult to predict parasitic capacitance generated between the first and second shielding layers SDL1 and SDL2 and the plurality of touch lines TL, touch driving may not be easily controlled.

Therefore, in the transparent display panel 110 according to one embodiment of the present disclosure, each of the first shielding layer SDL1 and the second shielding layer SDL2 can be used as the pixel power line VDDL and the common power line VSSL, so that the parasitic capacitance Cp6 can be prevented from occurring between the plurality of touch lines TL and the anode electrode 120 of the light emitting element OLED, and at the same time stable touch control can be performed.

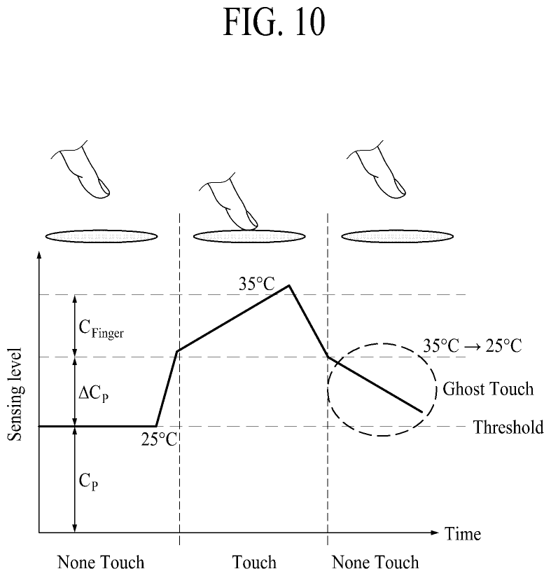

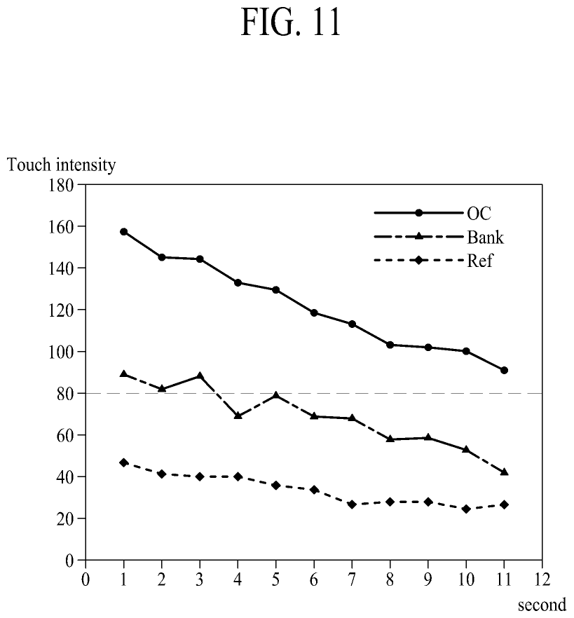

Also, in the transparent display panel 110 according to one embodiment of the present disclosure, the first and second shielding layers SDL1 and SDL2 are provided between the plurality of touch lines TL and the planarization layer PLN, so that a ghost touch defect can be prevented from occurring. Hereinafter, the ghost touch defect will be described in detail with reference to FIGS. 10 and 11.

FIG. 10 is a view illustrating a ghost touch defect phenomenon, and FIG. 11 is a view illustrating an influence of a planarization layer and a bank, which are provided in a transparent display panel, on a ghost touch defect.

Referring to FIG. 10, the touch sensor TS can generate a change in capacitance during a user's touch with the transparent display panel. The touch driver is connected to the plurality of touch sensors TS through the plurality of touch lines TL to sense a change in capacitance of the plurality of touch sensors TS.

In detail, when there is no user touch (None Touch), the touch sensor TS can sense a first value Cp. The first value Cp can correspond to a total amount of parasitic capacitance that affects the touch line TL and the touch sensor TS.

When the user's touch occurs (Touch), a predetermined capacitance Cfinger can occur between the user's finger and the touch sensor TS. In order to ensure high touch performance, it is important that the capacitance Cfinger between the user's finger and the touch sensor TS during the user's touch has a high value so that the first value Cp is maintained to be constant.

However, in an organic material, since the dielectric constant is changed depending on a temperature, a change in the first value Cp, which is a parasitic capacitance affecting the touch line TL and the touch sensor TS, can occur, whereby touch performance can be deteriorated. For example, a user's finger can heat on the touched area, which can cause a parasitic capacitance to linger after the user's finger has been removed.

For example, when there is no user's touch (None Touch), the touch sensor TS can sense the first value Cp as shown in FIG. 10. At this time, the temperature of the transparent display panel 110 can be, for example, 25° C.

When the user approaches to the transparent display panel 110 to touch the transparent display panel 110, the temperature of the transparent display panel 110 can be increased by a body temperature. At this time, the temperature of the organic material is increased and thus the dielectric constant can be changed. Therefore, a variation amount ΔCp is generated in the parasitic capacitance, so that the first value Cp+ΔCp can be increased.

When the user's touch occurs in the transparent display panel 110 (Touch), a predetermined capacitance Cfinger occurs between the user's finger and the touch sensor TS, and the touch driver can recognize the touch by sensing a capacitance change Cfinger of the touch sensor TS. At this time, the temperature of the transparent display panel 110 can be, for example, 35° C.

When the user's finger moves away from the transparent display panel 110, the touch driver preferably recognizes that the first value Cp is sensed from the touch sensor TS even though there is no touch present (e.g., the user's finger has since been removed). However, since the temperature of the transparent display panel 110 is gradually reduced from 35° C. to 25° C., the first value sensed from the touch sensor TS can be gradually reduced from Cp+ΔCp to Cp as shown in FIG. 10. In this situation, the touch driver may inadvertently recognize a touch although there is actually no touch, whereby a ghost touch defect can occur.

The ghost touch defect is generated due to a change in the dielectric constant of the organic material according to the temperature change as described above and thus can be caused by elements made of an organic material in the transparent display panel 110. In the transparent display panel 110, the elements made of an organic material disposed to be close to the plurality of touch lines TL can include the planarization layer PLN and the bank 125.

FIG. 11 shows touch intensity for each time from a time point when the user's finger is removed after the user's finger touch. In a transparent display panel Ref in which both the planarization layer PLN and the bank 125 are not provided, touch intensity is shown to be less than 80 at a period of 1 second to 11 seconds from the time point when the user's finger is removed. For example, it is assumed that the touch driver recognizes a touch when touch intensity is 80 or more. In this situation, the touch driver included in the transparent display panel Ref in which the planarization layer PLN and the bank 125 are not provided can determine that there is no touch from the time point when the user's finger is removed.

Meanwhile, in a transparent display panel Bank provided with the bank 125, touch intensity is 80 or more at a period of 1 second to 2 seconds from the time point when the user's finger was removed, and touch intensity is less than 80 at a period of 3 seconds to 11 seconds. The touch driver included in the transparent display panel Bank provided with the bank 125 can inadvertently determine that there is a touch from the time point when the user's finger was removed to 2 seconds later, even though the user's finger has been removed and is no longer present. That is, in the transparent display panel Bank provided with the bank 125, a ghost touch defect occurs for 2 seconds after the time point when the user's finger was removed.

Also, in a transparent display panel OC provided with the planarization layer PLN, touch intensity is 80 or more at a period of 1 second to 11 seconds after the time point when the user's finger is removed. The touch driver included in the transparent display panel OC provided with the planarization layer PLN can determine that there is a still touch from the time when the user's finger was removed to 11 seconds later, even though the user's finger has been removed and is no longer present. That is, in the transparent display panel OC provided with the planarization layer PLN, a ghost touch defect occurs for a long time after the time point when the user's finger was removed.

In view of a simulation result shown in FIG. 11, it is noted that the elements made of an organic material disposed to be close to the plurality of touch lines TL in the transparent display panel 110, that is, the planarization layer PLN and the bank 125 affect the ghost touch defect. Further, it is noted that the planarization layer PLN is disposed to closer to the touch lines TL than the bank 125 and has a wider formation area, thereby having a greater effect on a change in a dielectric constant according to temperature.

In the transparent display panel 110 according to one embodiment of the present disclosure, the shielding layer SDL is formed between the planarization layer PLN and the plurality of touch lines TL, whereby the plurality of touch lines TL can be prevented from forming a parasitic capacitance with another signal line or electrode with the planarization layer PLN interposed therebetween. Therefore, the transparent display panel 110 according to one embodiment of the present disclosure can greatly reduce the influence on the touch line TL even though the dielectric constant is changed due to the temperature increase of the planarization layer PLN. That is, the transparent display panel 110 according to one embodiment of the present disclosure can minimize occurrence of the ghost touch defect by placing shielding layer SDL is formed between the planarization layer PLN and the plurality of touch lines TL and/or between the bank 125 and the plurality of touch lines TL.

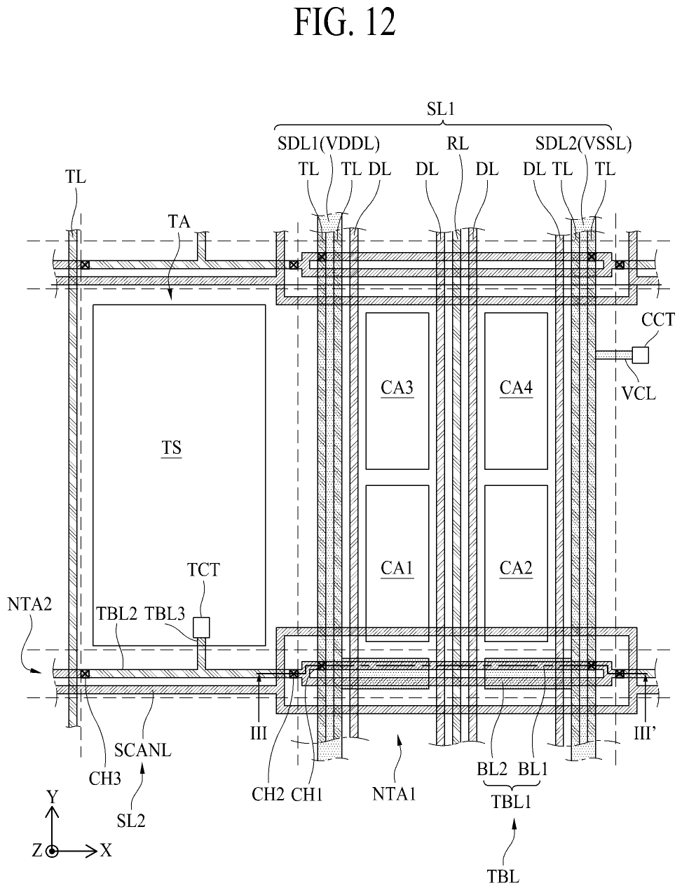

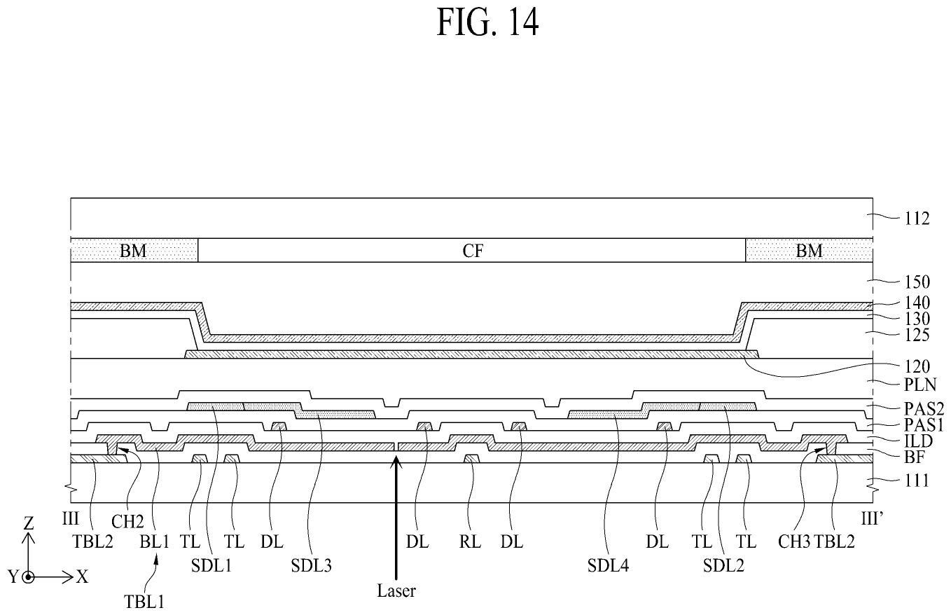

FIG. 12 is a view illustrating another example of signal lines, touch lines, a touch sensor and a shielding layer, which are provided in an area B of FIG. 2, FIG. 13 is a cross-sectional view illustrating an example of line III-III′ of FIG. 12, and FIG. 14 is a cross-sectional view illustrating an example of a first branch line cut by laser.

The transparent display panel 110 according to another embodiment of the present disclosure, which is shown in FIGS. 12 to 14, differs from the transparent display panel 110 shown in FIGS. 3, 6 and 7 in a shielding layer SDL, and its other elements are substantially the same as those of the transparent display panel 110 shown in FIGS. 3, 6 and 7. Hereinafter, only differences from the transparent display panel shown in FIGS. 3, 6 and 7 will be described in detail and the description of substantially the same elements as those shown in FIGS. 3, 6 and 7 will be omitted.

Referring to FIGS. 12 to 14, the transparent display panel 110 according to another embodiment of the present disclosure can be provided with the shielding layer SDL between first and second passivation layers PAS1 and PAS2. The shielding layer SDL can be extended in a first direction (e.g., Y-axis direction) along touch lines TL on the touch lines TL. The shielding layer SDL can be provided to overlap with at least a portion of the touch lines TL.

A plurality of shielding layers SDL can be provided, each of which can be provided to overlap with at least one of the plurality of touch lines TL. At least one touch line TL can be disposed in each of at least two areas spaced apart from each other. In this situation, the shielding layer SDL can be provided in each of the at least two areas. At this time, one shielding layer SDL can overlap with one touch line TL while having a width covering one touch line TL. Alternatively, one shielding layer SDL can overlap two or more touch lines while having a width covering the two or more touch lines TL.

For example, in one first non-transmissive area NTA1, two first touch lines TL can be disposed between circuit areas CA1, CA2, CA3 and CA4 and a transmissive area TA disposed at a left side of the circuit areas CA1, CA2, CA3 and CA4. Two second touch lines TL can be disposed between the circuit areas CA1, CA2, CA3 and CA4 and the transmissive area TA disposed at a right side of the circuit areas CA1, CA2, CA3 and CA4.

In this situation, the shielding layer SDL can include a first shielding layer SDL1 and a second shielding layer SDL2. The first shielding layer SDL1 can be provided over two first touch lines TL disposed between the circuit areas CA1, CA2, CA3 and CA4 and the transmissive area TA disposed at the left side of the circuit areas CA1, CA2, CA3 and CA4. The first shielding layer SDL1 can be provided to overlap with two first touch lines TL while having a width covering the two first touch lines TL.

The second shielding layer SDL2 is disposed to be spaced apart from the first shielding layer SDL1, and can be provided over two second touch lines TL disposed between the circuit areas CA1, CA2, CA3 and CA4 and the transmissive area TA disposed at the right side of the circuit areas CA1, CA2, CA3 and CA4. The second shielding layer SDL2 can be provided to overlap with two second touch lines TL while having a width covering the two second touch lines TL.

Also, the shielding layer SDL can be extended in a second direction (e.g., X-axis direction) along a first touch bridge line TBL1 over the first touch bridge line TBL1. The shielding layer SDL can be provided to overlap with at least a portion of the first touch bridge line TBL1.

The shielding layer SDL can further include a third shielding layer SDL3 and a fourth shielding layer SDL4. For example, the third shielding layer SDL3 and the fourth shielding layer SDL4 can be disposed between two adjacent portions of the second shielding layer SDL2. Also, the third shielding layer SDL3 and the fourth shielding layer SDL4 can be symmetrically arranged relative to the reference line RL, but embodiments are not limited thereto. The third shielding layer SDL3 can be protruded from one side of the first shielding layer SDL1 and extended in the second direction (e.g., X-axis direction) toward the second shielding layer SDL2. The third shielding layer SDL3 can be provided to overlap with at least a portion of the first touch bridge line TBL1 on the first touch bridge line TBL1. When the first touch bridge line TBL1 includes a first branch line BL1 and a second branch line BL2, the third shielding layer SDL3 can be provided to overlap with at least a portion of the first and second branch lines BL1 and BL2 while having a width covering the first and second branch lines BL1 and BL2.

The fourth shielding layer SDL4 can be protruded from one side of the second shielding layer SDL2 and extended in the second direction (e.g., X-axis direction) toward the first shielding layer SDL1. The fourth shielding layer SDL4 can be provided to overlap with at least a portion of the first touch bridge line TBL1 on the first touch bridge line TBL1. When the first touch bridge line TBL1 includes a first branch line BL1 and a second branch line BL2, the fourth shielding layer SDL4 can be provided to overlap with at least a portion of the first and second branch lines BL1 and BL2 while having a width covering the first and second branch lines BL1 and BL2.

The fourth shielding layer SDL4 can be disposed to be spaced apart from the third shielding layer SDL3. At least a portion of each of the first and second branch lines BL1 and BSL2 can be exposed without being covered by the third and fourth shielding layers SDL3 and SDL4. When any one of the first separation line BL1 and the second branch line BL2 is short-circuited with another signal line, in the transparent display panel 110 according to another embodiment of the present disclosure, the area of the short-circuited branch line, which is exposed without being covered by the third and fourth shielding layers SDL3 and SDL4, can be cut by laser, as shown in FIG. 14.

In one embodiment, the first to fourth shielding layers SDL1, SDL2, SDL3 and SDL4 can include a conductive material. The first to fourth shielding layers SDL1, SDL2, SDL3 and SDL4 can be formed as a single layer or multi-layer made of any one of molybdenum (Mo), aluminum (Al), chromium (Cr), gold (Au), titanium (Ti), nickel (Ni), neodymium (Nd), copper (Cu) and ITO or their alloy. For example, the first to fourth shielding layers SDL1, SDL2, SDL3 and SDL4 can include an alloy of molybdenum (Mo) and titanium (Ti) or a stacked structure of an alloy of molybdenum (Mo) and titanium (Ti) and ITO.

In one embodiment, the first to fourth shielding layers SDL1, SDL2, SDL3 and SDL4 can be power lines for supplying a power source to the subpixels SP1, SP2, SP3 and SP4. Each of the first shielding layer SDL1, the second shielding layer SDL2, the third shielding layer SDL3 and the fourth shielding layer SDL4 can be one of the pixel power line VDDL and the common power line VSSL. For example, the first shielding layer SDL1 and the third shielding layer SDL3 can be pixel power lines VDDL for supplying a first power source to the driving transistors DTR of each of the subpixels SP1, SP2, SP3 and SP4. The second shielding layer SDL2 and the fourth shielding layer SDL4 can be a common power line VSSL for supplying a second power source to a cathode electrode of the subpixels SP1, SP2, SP3 and SP4.

The transparent display panel 110 according to one embodiment of the present disclosure can form at least a portion of the pixel power line VDDL, the common power line VSSL, the reference line RL, the data lines DL, the touch lines TL and the touch bridge line TBL on the same layer as the first to fourth shielding layers SDL1, SDL2, SDL3 and SDL4.

In the transparent display panel 110 according to another embodiment of the present disclosure, the plurality of touch lines TL can be provided on the same layer as the light-shielding layer LS and made of a same material, thereby making sure of a maximum distance away from the anode electrode 120 of the light emitting element OLED.

Moreover, the transparent display panel 110 according to another embodiment of the present disclosure can include first and second shielding layers SDL1 and SDL2 between the plurality of touch lines TL and the anode electrode 120 of the light emitting element OLED. Therefore, the transparent display panel 110 according to another embodiment of the present disclosure can block or minimize the occurrence of parasitic capacitance between the plurality of touch lines TL and the anode electrode 120 of the light emitting element OLED.

Also, the transparent display panel 110 according to another embodiment of the present disclosure can include third and fourth shielding layers SDL3 and SDL4 between the first touch bridge line TBL1 electrically connected to any one of the plurality of touch lines TL and the anode electrode 120 of the light emitting element OLED. The first touch bridge line TBL1 can be provided on a layer different from the light-shielding layer LS. For example, the first touch bridge line TBL1 can be disposed on the same layer as the gate electrode GE of the driving transistor DTR and made of a same material. Since the first touch bridge line TBL1 is disposed on the light-shielding layer LS, a distance from the anode electrode 120 can be shorter than that from the touch lines TL. Therefore, the parasitic capacitance between the first touch bridge line TBL1 and the anode electrode 120 can be greater than the parasitic capacitance between the touch lines TL and the anode electrode 120.

The transparent display panel 110 according to another embodiment of the present disclosure includes the third and fourth shielding layers SDL3 and SDL4 between the first touch bridge line TBL1 and the anode electrode 120 of the light emitting element OLED, whereby occurrence of the parasitic capacitance between the first touch bridge line TBL1 and the anode electrode 120 of the light emitting element OLED can be blocked or minimized.

The transparent display panel 110 according to another embodiment of the present disclosure can minimize parasitic capacitance between the plurality of touch lines TL and the anode electrode 120 of the light emitting element OLED and between the first touch bridge line TBL1 and the anode electrode 120 of the light emitting element OLED. Therefore, the touch recognition rate of the transparent display panel 110 according to another embodiment of the present disclosure can be significantly improved. In addition, a current can occur more stably in the light emitting element OLED.

Also, in the transparent display panel 110 according to another embodiment of the present disclosure, the first to fourth shielding layers SDL1, SDL2, SDL3 and SDL4 can be used as the pixel power lines VDDL or the common power lines VSSL. Therefore, in the transparent display panel 110 according to another embodiment of the present disclosure, since the first to fourth shielding layers SDL1, SDL2, SDL3 and SDL4, the pixel power line VDDL and the common power line VSSL do not need to be provided in a separate layer or area, the first to fourth shielding layers SDL1, SDL2, SDL3 and SDL4 can be provided without increasing the size of the first non-transmissive area NTA1. As a result, the transparent display panel 110 according to another embodiment of the present disclosure can include the first to fourth shielding layers SDL1, SDL2, SDL3 and SDL4 without loss of light transmittance.

Also, in the transparent display panel 110 according to another embodiment of the present disclosure, the first and third shielding layers SDL1 and SDL3 can be used as the pixel power lines VDDL, and the second and fourth shielding layers SDL2 and SDL4 can be used as the common power lines VSSL. In this situation, in the transparent display panel 110 according to another embodiment of the present disclosure, a first power source can be applied to the first and third shielding layers SDL1 and SDL3, and a second power source can be applied to the second and fourth shielding layers SDL2 and SDL4. In the transparent display panel 110 according to another embodiment of the present disclosure, since a constant voltage is applied to the first to fourth shielding layers SDL1, SDL2, SDL3 and SDL4, parasitic capacitance generated between the first to fourth shielding layers SDL1, SDL2, SDL3 and SDL4 and the plurality of touch lines TL can be predicted and remain stable, thereby facilitating touch control. In addition, the transparent display panel 110 according to another embodiment of the present disclosure can reduce touch driving noise and improve touch sensing accuracy.

In the transparent display panel 110 according to another embodiment of the present disclosure, the first and second shielding layers SDL1 and SDL2 can be provided between the plurality of touch lines TL and the planarization layer PLN, and the third and fourth shielding layers SDL3 and SDL4 can be provided between the first touch bridge line TBL1 and the planarization layer PLN. In the transparent display panel 110 according to another embodiment of the present disclosure, the first touch bridge line TBL1 can be prevented from forming a parasitic capacitance with another signal line or electrode with the planarization layer PLN interposed therebetween. Therefore, the transparent display panel 110 according to another embodiment of the present disclosure can greatly reduce the influence on the touch line TL and the first touch bridge line TBL1 even though the dielectric constant is changed due to the temperature increase of the planarization layer PLN. That is, the transparent display panel 110 according to another embodiment of the present disclosure can minimize occurrence of the ghost touch defect.

Also, in the transparent display panel 110 according to another embodiment of the present disclosure, the third shielding layer SDL3 and the fourth shielding layer SDL4 can be disposed to be spaced apart from each other, so that a space for irradiating laser to one of the first separation line BL1 and the second branch line BL2, in which a short circuit occurs, can be obtained even though the third shielding layer SDL3 and the fourth shielding layer SDL4 are formed. In other words, a gap is provided between third shielding layer SDL3 and the fourth shielding layer SDL4 allow for the ability and provide enough space to be able to cut a touch bridge line with a laser if necessary (e.g., the touch bridge line may not be fully covered by the shielding layers).

In the present disclosure, the touch sensor electrode of the touch sensor and the cathode electrode of the light emitting element can be simultaneously formed using the undercut structure, whereby the touch process can be simplified and an additional separate mask for forming the touch sensor electrode is not required. Therefore, the present disclosure can implement process optimization, reduce production energy, and produce a device that has a thinner profile.

Also, in the present disclosure, the plurality of touch lines can be provided on the same layer as the shielding layer to ensure a maximum distance away from the anode electrode of the light emitting element. Furthermore, in the present disclosure, the shielding layer can be provided between the plurality of touch lines and the anode electrode of the light emitting element, whereby occurrence of parasitic capacitance between the plurality of touch lines and the anode electrode of the light emitting element can be minimized or prevented. As a result, the touch recognition rate can be improved, and the current of the light emitting element can be stably generated to prevent any flickering caused by a luminance deviation from occurring, which improves image quality.

Also, in the present disclosure, the shielding layer can be disposed between the planarization layer and the plurality of touch lines so that the plurality of touch lines can be prevented from forming parasitic capacitance with another signal line or electrode with the planarization layer interposed therebetween. Therefore, even though the dielectric constant is changed due to the temperature increase of the planarization layer due to heat transfer from the user's finger, the influence on the touch line can be greatly reduced, and occurrence of the ghost touch defect can be minimized or prevented.

Also, in the present disclosure, the shielding layer can be used as the pixel power line to which the first power source is applied and the common power line to which the second power source is applied. In the present disclosure, since a constant voltage is applied to the shielding layer, parasitic capacitance generated between the shielding layer and the plurality of touch lines can be predicted and remain stable, thereby facilitating touch control. Furthermore, touch driving noise can be reduced, and thus stable touch control can be performed.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims, and it is intended that all variations or modifications derived from the meaning, scope and equivalent concept of the claims fall within the scope of the present disclosure.

What is claimed is:

1. A transparent display device with a touch sensor, the transparent display device comprising:
a plurality of subpixels disposed in a non-transmissive area of a substrate, the plurality of subpixels including a light emitting element having an anode electrode, a light emitting layer and a cathode electrode;
a touch sensor disposed in a transmissive area of the substrate, the touch sensor including a touch sensor electrode;
a touch line disposed between the substrate and the anode electrode in the non-transmissive area, the touch line being configured to supply a touch sensing voltage to the touch sensor; and
a shielding layer disposed between the touch line and the anode electrode in the non-transmissive area.

2. The transparent display device of claim 1, wherein the touch line extends in a first direction, and
wherein the shielding layer extends in the first direction along the touch line.

3. The transparent display device of claim 1, wherein the shielding layer overlaps with at least a portion of the touch line.

4. The transparent display device of claim 1, wherein the touch line includes a plurality of touch lines, and
wherein the shielding layer at least partially overlaps with the plurality of touch lines, and a width of the shielding layer covers the plurality of touch lines.

5. The transparent display device of claim 1, further comprising:
a driving transistor disposed on the substrate, the driving transistor including an active layer, a gate electrode, a source electrode and a drain electrode; and
a light-shielding layer disposed between the substrate and the driving transistor, the light-shielding layer at least partially overlapping with the driving transistor,
wherein the touch line and the light-shielding layer are disposed on a same layer.

6. The transparent display device of claim 5, wherein the shielding layer and the driving transistor are disposed on different layers.

7. The transparent display device of claim 1, further comprising a planarization layer disposed between the shielding layer and the anode electrode.

8. The transparent display device of claim 1, wherein the touch line includes a first touch line and a second touch line spaced apart from the first touch line, and
wherein the shielding layer includes a first shielding layer overlapping with at least a portion of the first touch line and a second shielding layer overlapping with at least a portion of the second touch line.

9. The transparent display device of claim 8, wherein the first touch line and the second touch line extend in the first direction,
wherein the first shielding layer extends in the first direction along the first touch line, and the second shielding layer extends in the first direction along the second touch line.

10. The transparent display device of claim 8, wherein the first shielding layer and the second shielding layer are spaced apart from each other.

11. The transparent display device of claim 8, wherein the first shielding layer and the second shielding layer include a conductive material.

12. The transparent display device of claim 11, wherein the first shielding layer is a pixel power line configured to supply a first power source to the anode electrode, and
wherein the second shielding layer is a common power line configured to supply a second power to the cathode electrode.

13. The transparent display device of claim 1, further comprising a touch bridge line disposed between the substrate and the anode electrode in the non-transmissive area, the touch bridge line electrically connecting the touch line with the touch sensor,
wherein the shielding layer is disposed between the touch bridge line and the anode electrode in the non-transmissive area.

14. The transparent display device of claim 13, wherein the shielding layer overlaps with at least a portion of the touch bridge line.

15. The transparent display device of claim 13, further comprising a driving transistor disposed on the substrate, the driving transistor including an active layer, a gate electrode, a source electrode and a drain electrode,
wherein the touch bridge line is disposed on a same layer as at least one of the gate electrode, the source electrode and the drain electrode.

16. The transparent display device of claim 13, wherein the touch line includes a first touch line disposed at a first side of the plurality of subpixels and a second touch line disposed on a second side of the plurality of subpixels, and
wherein the shielding layer includes:
a first shielding layer overlapping with at least a portion of the first touch line,
a second shielding layer overlapping with at least a portion of the second touch line,
a third shielding layer protruding from one side of the first shielding layer and overlapping with a portion of the touch bridge line, and
a fourth shielding layer protruding from one side of the second shielding layer and provided to overlap another portion of the touch bridge line.

17. The transparent display device of claim 16, wherein the third shielding layer and the fourth shielding layer are disposed to be spaced apart from each other with a gap between the third shielding layer and the fourth shielding layer.

18. The transparent display device of claim 16, wherein the touch bridge line includes an exposed portion between the third shielding layer and the fourth shielding layer,
wherein the exposed portion of the touch bridge line is not covered by the third shielding layer and the fourth shielding layer.

19. The transparent display device of claim 13, wherein the touch bridge line includes a first touch bridge line extending in a second direction between the plurality of subpixels,
wherein the first touch bridge line includes a first branch line and a second branch line, the first and second branch lines being connected to each other at one or more portions, and
wherein the shielding layer overlaps with at least a portion of the first branch line and at least a portion of the second branch line.

20. The transparent display device of claim 19, wherein the touch bridge line includes:
a second touch bridge line electrically connected to the first touch bridge line, the second touch bridge line extending in the second direction, and
a third touch bridge line protruding from the second touch bridge line, the third bridge touch line extending to an area overlapping with the touch sensor, and
wherein the shielding layer does not overlap with the second touch bridge line and the third touch bridge line.

21. The transparent display device of claim 1, wherein the cathode electrode in the light emitting element and the touch sensor electrode in the touch sensor are disposed on a same layer.

22. The transparent display device of claim 1, wherein the cathode electrode in the light emitting element and the touch sensor electrode in the touch sensor are separated from each other by an undercut structure.

23. The transparent display device of claim 22, wherein the undercut structure has a closed loop shape in a plane view in the transmissive area.

24. The transparent display device of claim 22, wherein the undercut structure extends around an outer perimeter of the touch sensor electrode.

25. The transparent display device of claim 22, wherein the undercut structure includes a trench or a hole in one or more insulating layers.

26. The transparent display device of claim 22, wherein the cathode electrode in the light emitting element and the touch sensor electrode in the touch sensor are made from a same material.

27. A transparent display device with a touch sensor, the transparent display device comprising:
a plurality of subpixels disposed in a non-transmissive area of a substrate, the plurality of subpixels including a light emitting element having an anode electrode, a light emitting layer and a cathode electrode;
a touch sensor disposed in a transmissive area of the substrate, the touch sensor including a touch sensor electrode;
a touch bridge line disposed between the substrate and the anode electrode in the non-transmissive area,
wherein a portion of the anode electrode in the light emitting element overlaps with a portion of the touch bridge line, and no metal layers between portion of the anode electrode in the light emitting element overlaps with a portion of the touch bridge line.

28. The transparent display device of claim 27, wherein the portion of the touch bridge line is configured to be cut by a laser.

29. A transparent touch display device, comprising:
a light emitting element including an anode electrode, a light emitting layer and a cathode electrode;
a first transparent touch sensor;
a first touch line configured to supply a touch sensing voltage to the first transparent touch sensor; and
a power line disposed between the touch line and the anode electrode, the power line being configured to supply a driving voltage to the light emitting element.

30. The transparent touch display device of claim 29, wherein a width of the power line is greater than a width of the first touch line.

31. The transparent touch display device of claim 30, further comprising:
a second transparent touch sensor; and
a second touch line configured to supply the touch sensing voltage to the second transparent touch sensor,
wherein the width of the power line overlaps with both of the first touch line and the second touch line.

32. The transparent touch display device of claim 30, wherein the power line extends in a second direction and includes a plurality of protrusions that extend in a first direction.

33. The transparent touch display device of claim 32, further comprising:
a plurality of touch bridge lines extending in the first direction,
wherein each of the plurality of protrusions of the power line overlaps with at least a portion of one of the plurality of touch bridge lines.

34. The transparent touch display device of claim 33, wherein a touch bridge line among the plurality of touch bridge lines includes a first touch bridge branch portion and a second touch bridge branch portion, the second touch bridge branch portion being spaced apart from the first touch bridge branch portion.

35. The transparent touch display device of claim 34, wherein one of the plurality of protrusions of the power line overlaps with the first touch bridge branch portion and the second touch bridge branch portion.

36. The transparent touch display device of claim 34, further comprising:
a plurality of scan lines extending in the first direction,
wherein a scan line among the plurality of scan lines includes a first scan branch portion and a second scan branch portion, the second scan branch portion being spaced apart from the first scan branch portion.

37. The transparent touch display device of claim 36, wherein the first and second touch bridge branch portions of the touch bridge line surround the first and second scan branch portions of the scan line.

38. The transparent touch display device of claim 37, wherein one of the plurality of protrusions of the power line is disposed between the first and second scan branch portions of the scan line and overlaps with the first touch bridge branch portion and the second touch bridge branch portion.
